(19) United States
(12) Patent Application Publication
(10) Pub. No.: US 2014/0353577 A1
(43) Pub. Date: Dec. 4, 2014

(54) EMISSION IN NANOSCALE STRUCTURES VIA NANOCAVITY PLASMONS

(71) Applicants: Ritesh Agarwal, Philadelphia, PA (US); Chang-Hee Cho, Philadelphia, PA (US); Carlos O. Aspetti, King of Prussia, PA (US)

(72) Inventors: Ritesh Agarwal, Philadelphia, PA (US); Chang-Hee Cho, Philadelphia, PA (US); Carlos O. Aspetti, King of Prussia, PA (US)

(21) Appl. No.: 14/359,673

(22) PCT Filed: Nov. 21, 2012
(86) PCT No.: PCT/US2012/066184

§ 371 Date: May 21, 2014

Related U.S. Application Data
(60) Provisional application No. 61/562,685, filed on Nov. 22, 2011.

(51) Int. Cl. H01L 49/00

(52) U.S. Cl. CPC H01L 49/006
USPC 257/10

(57) ABSTRACT

Plasmonic nanoscale devices with increased emissions are disclosed. Highly concentrated fields of plasmonic nanocavities are integrated with a core to alter the excited-state optical processes. A plasmonic device (e.g., a nanowire) is created using a direct or indirect bandgap material core, an interlayer and a metallic shell.

### RELATED APPLICATION

This application claims priority to U.S. application 61/562,685, “Emission in Nanowires Via Nanocavity Plasmons,” filed Nov. 22, 2011, the entirety of which is incorporated herein for any and all purposes.

### GOVERNMENT RIGHTS

This invention was made with government support under Grant No. W911NF0910477 awarded by the Army Research Office and under Grant No. DP2 OD007251-01 awarded by the National Institutes of Health. The government has certain rights in the invention.

### TECHNICAL FIELD

The present disclosure is directed to the field of nanoscale devices. The present disclosure is also directed to the field of enhancing emissions in nanoscale devices.

### BACKGROUND

The manipulation of radiative properties of light emitters coupled with surface plasmons is important for engineering new nanoscale optoelectronic devices, including lasers, detectors and single photon emitters. However, so far the radiative rates of excited states in semiconductors and molecular systems have been enhanced only moderately, typically by a factor of 10-50, producing emission mostly from thermalized excitons.

In direct-bandgap semiconductors, optical excitation with energies greater than the exciton ground state is followed by rapid relaxation of the excess energy of the exciton by emission of longitudinal optical (LO) phonons and eventually by interactions with acoustic phonons to thermalize to k˜0 momentum states. The relaxation timescales of LO and acoustic phonons are typically sub-picosecond and ˜100 ps respectively and are much faster than the exciton recombination timescale (>ns). As the relaxation processes for LO phonons are much faster than the exciton radiative decay, hot-exciton emission has typically been observed only in high-quality crystals or specially designed quantum-well structures that decrease the exciton lifetime. However, even when hot-exciton emission has been observed it is only with very low emission yields. Achieving accurate control over the emissive properties of the exciton states is critical to design nanoscale photonic devices and also to study their fine structure, which may not be possible when recombination occurs from thermalized excitons.

Although some have reported on modifying the optical properties of emitters placed near metallic nanostructures, they have focused on modifying normal luminescence. Hot electroluminescence has been observed in molecules placed between a metallic nanotip and a substrate, but the emission intensities were very low and the underlying physics remains to be clarified.

Semiconducting nanowires placed in the vicinity of flat metal substrates have shown a decrease in their radiative lifetime to ˜100 ps; however, this is not enough to significantly modify their emission properties, as this timescale is comparable to the interactions of acoustic phonons, which mostly thermalize the excitons.

Resonant plasmonic nanocavities have the potential to significantly modify the excited-state relaxation processes by means of near-field coupling of strongly enhanced electromagnetic fields with excitons to provide enhanced light emitters. Furthermore, plasmonic nanocavities integrated with semiconducting nanowires in a core-shell architecture can be tuned in and out of resonance with lower-order plasmonic whispering gallery modes by using the nanowire diameter to manipulate their optical response in order to further enhance light emitters.

### SUMMARY

One object of the present invention is a nanowire with increased emissions.

Another object of the present invention is a nanowire employing plasmonic nanocavities.

Still yet another object of the present invention is a plasmonic device that include an indirect bandgap material core.

Still yet another object of the present invention is a plasmonic device wherein a diameter of the core corresponds to a resonant mode of the plasmonic cavity.

An aspect of the present invention is a plasmonic device comprising: a core composed of a direct bandgap material; an interlayer surrounding the nanowire; and a metallic shell surrounding the interlayer.

Another aspect of the present invention is a plasmonic nanoscale device comprising: a core composed of a bandgap material having a diameter; an interlayer surrounding the nanowire; a metallic shell surrounding the interlayer; and wherein a plasmonic nanocavity is formed and a diameter of the core or a thickness of the interlayer corresponds to a plasmonic resonant cavity mode.

This disclosure also provides plasmonic nanowires, comprising: a core that comprises a direct bandgap material; an interlayer that at least partially surmounts the core; and a shell that at least partially surmounts the interlayer.

Also disclosed are plasmonic nanowires, comprising a core having a diameter and comprising a bandgap material; an interlayer having a thickness and at least partially surmounting the core; and a shell at least partially surmounting the interlayer, wherein a plasmonic nanocavity is formed and a diameter of the core or a thickness of the interlayer corresponds to a plasmonic resonant cavity mode.

Additionally provided are plasmonic nanowires, comprising a core having a diameter and comprising an indirect bandgap material; an interlayer having a thickness and at least partially surmounting the core; and a shell that at least partially surmounts the interlayer.

Further provided are emitters, comprising: a excitation source; a plasmonic nanowire comprising a core having a diameter and comprising a bandgap material; an interlayer having a thickness and at least partially surmounting the core; a metallic shell that at least partially surmounts the interlayer, wherein a diameter of the core or a thickness of the interlayer corresponds to the plasmonic resonant cavity mode of the plasmonic nanowire; and a detector capable of detecting an emission from the plasmonic nanowire.

Still yet another aspect of the present invention may be a plasmonic nanowire comprising: a core composed of an indirect bandgap material; an interlayer surrounding the nanowire; and a metallic shell surrounding the interlayer.

Another aspect of the present invention may be an emitter comprising: An emitter comprising: a source; a plasmonic nanowire comprising: a core composed of a bandgap material; an interlayer surrounding the nanowire; a metallic shell surrounding the interlayer; wherein a diameter of the core or a thickness of the interlayer corresponds to the plasmonic resonant cavity mode; and a detector (e.g, a PMT, a CCD, and the like).

These and various other advantages and features of novelty that characterize the invention are pointed out with particularity in the claims annexed hereto and forming a part hereof. However, for a better understanding of the invention, its advantages, and the objects obtained by its use, reference should be made to the drawings which form a further part hereof, and to the accompanying descriptive matter, in which there is illustrated and described a preferred embodiment of the invention.

### BRIEF DESCRIPTION OF THE DRAWINGS

The summary, as well as the following detailed description, is further understood when read in conjunction with the appended drawings. For the purpose of illustrating the invention, there are shown in the drawings exemplary embodiments of the invention; however, the invention is not limited to the specific methods, compositions, and devices disclosed. In addition, the drawings are not necessarily drawn to scale or proportion. In the drawings:

FIG. 1 shows a diagram of a plasmonic nanowire and layers;

FIG. 2 shows a graph of the intensity of passivated and unpassivated nanowires;

FIGS. 3a-3d show hot-exciton emission from plasmonic and photonic nanowires;

FIG. 4 shows a graph of the intensity of plasmonic wires at different excitations;

FIG. 5 shows a graph of the intensity obtained using a planar Ag film;

FIGS. 6a-6d show temperature and polarization dependent properties of the hot exciton emission;

FIG. 7 shows a diagram of A and B exciton dispersion;

FIGS. 8a-8e show the size-dependent properties of the whispering-gallery plasmon nanocavity;

FIG. 9 shows the calculated field distribution of the magnetic field intensity and electric field intensity for the various resonance modes;

FIG. 10 is a graph of the compared intensity between the photonic and plasmonic nanowires;

FIGS. 11a and 11b are diagrams of a nanowire using indirect bandgap material for the core;

FIG. 12 is a schematic of a silicon band structure showing the hot carrier emission process;

FIG. 13 shows the photoluminescence spectrum of the indirect-gap material light emitting device.

FIG. 14 is an optical micrograph showing the photoluminescence of the silicon plasmonic nanowire;

FIG. 15 is a diagram of an omega shaped plasmonic nanowire;

FIG. 16 is a diagram of a system in which a plasmonic nanowire is used;

FIG. 17 illustrates hot luminescence from silicon coupled to a plasmon nanocavity. a, Schematic of the electronic band diagram of bulk crystalline silicon illustrating phonon-assisted hot luminescence processes before the thermalization of the carriers to the minimum of the conduction band near the X-point. b, Schematic of an Ω-shaped plasmonic nanocavity coupled silicon nanowire device. c, Scanning electron microscope (SEM) image of the fabricated device. d and e, Optical images of a single-plasmonic silicon nanowire device obtained through the glass substrate under white light (d), and a focused laser excitation (e). f, Room-temperature photoluminescence spectra from single silicon nanowire device coupled with a Ω-shaped cavity (100 nm Ag film) having the silicon nanowire diameter, d, of 65 nm. Spectrum of a 5 nm SiO₂ coated single silicon nanowire without a plasmonic cavity (lower line; d=60 nm) is also shown, with no observable photon counts without the plasmonic cavity;

FIG. 18 illustrates resonantly enhanced hot luminescence in plasmonic silicon. a, Room-temperature photoluminescence spectrum from a single silicon nanowire coupled with Ω-shaped plasmon nanocavity (d=70 nm). The calculated frequency-dependent electromagnetic field intensity inside the cavity reproduces the resonances correctly. b to d, Calculated electric field profile at cavity resonance energies of 2.505 eV (b), 2.342 eV (c), and (d) 2.179 eV labeled as A, B, and C on the spectrum, showing the formation of plasmonic cavity modes. The corresponding magnetic field intensities of the cavity modes are provided in the FIG. 22. The white outlines refer to the Si—SiO₂—Ag interfaces of the Ω-shaped cavity structure.

FIG. 19 illustrates polarization-selective spectra for resonant and nonresonant plasmonic silicon devices. a, Polarization-resolved hot luminescence spectra for a resonant-sized plasmonic cavity coupled silicon nanowire (d=70 nm) showing anisotropic emission polarized predominantly perpendicular to the nanowire's long axis. The strong emission bands are exactly overlapped with the calculated energy-dependent field intensity inside the cavity showing resonances. b, The same measurement procedure was followed for a nonresonant-sized plasmonic cavity coupled silicon nanowire device (d=50 nm). Both the cavity modes (“C”) and hot luminescence bands (“P”) corresponding to phonons with high density of states are revealed on the perpendicularly polarized emission spectrum. The cavity modes are confirmed by the calculated cavity field intensity as a function of energy. c, Calculated field intensity spectra inside the plasmon cavities as a function of nanowire diameter. The white dashed lines indicate the three strong hot luminescence bands, corresponding to the phonon modes with high density of states. d, Experimental size-dependent photoluminescence spectra for the nanowires with diameter ranging from 40 to 80 nm. Calculated spectra for cavity field intensity (dashed lines) are also plotted to show the resonant and non-resonant conditions between the cavity modes and the highly emissive hot luminescence bands;

FIG. 20 illustrates photoluminescence spectrum from a single silicon nanowire (diameter, d, 45 nm) device coupled with an Ω-shaped plasmon nanocavity under UV laser excitation at 3.486 eV (tunable frequency doubled, femtosecond Ti:Sapphire laser) at room temperature;

FIG. 21 illustrates (a) room-temperature photoluminescence spectrum showing the visible hot luminescence collected from 4 bowtie plasmon nanocavities on planar silicon substrate. Calculated spectrum of energy-dependent field intensity is also shown. Inset; SEM image of the device showing planar single crystalline silicon coupled with Ag bowtie plasmon nanocavities. Scale bar, 200 nm. b and c, Calculated electric field profiles in the bowtie device. Top view (b) and cross-sectional view (c) at a resonance energy of 2.32 eV. The bowtie structure is outlined in white. Simulations reveal strongly enhanced fields are formed between the tips of both triangles of the bowties, which penetrate ˜80 nm into the underlying Si substrate. However, bigger mode volumes and imperfect matching to the high-density phonon modes of silicon results in lower emission intensity;

FIG. 22 illustrates calculated magnetic field profile for the 70 nm diameter plasmonic silicon nanowire device at the resonance energies of 2.505 eV (a), 2.342 eV (b), and 2.179 eV (c), showing the plasmonic cavity modes;

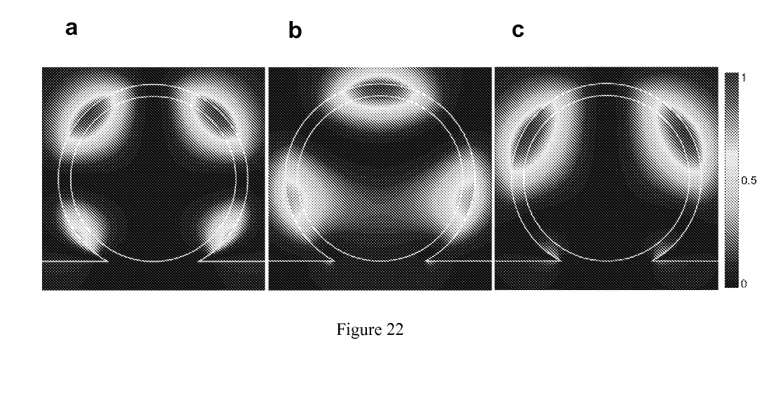

FIG. 23 illustrates a calculated electric field profile along the Si wire axis (coupled with an Ω-shaped cavity) by 3D simulation showing a confined cavity mode (resonance mode B in FIG. 18c) in the cross-sectional plane perpendicular to the wire axis. The field profile is taken 15 nm away from the top surface, in the antinode regions of the electric field for the mode. The decay length of the mode along the nanowire's long axis is ˜200 nm;

FIG. 24 illustrates a calculated position-dependent Purcell factor map for the silicon core coupled with an Ω-shaped plasmonic cavity (d=70 nm) at the resonance energy of 2.51 eV, showing Purcell factors decreasing from the surface with values of ˜10³ (within <5 nm away from the surface) and ˜10² enhancement throughout the majority of the nanowire core. The white outline refers to the SiO₂—Ag interface of the Ω-shaped cavity. Only the values inside the Si nanowire are shown for clarity;

FIG. 25 illustrates a, Excitation energy dependence of photoluminescence spectra, showing a shift of phonon-assisted hot luminescence peak positions under 2.331 eV (upper) and 2.708 eV (lower) laser excitation (d˜50 nm). In order to compare the phonon-related peak positions at the same spectral energy range, the spectrum for 2.708 eV excitation was taken from FIG. 19b. b, Polarization-selective spectra under 2.331 eV laser excitation (d˜60 nm), showing a similar overall peak structure and almost the same energy difference between the peaks and the excitation energy just as that under 2.708 eV excitation (FIG. 19a). The first two “P” peaks at 2.164 and 2.133 eV correspond to the peaks “1” and “2” in FIG. 19a, while the broad “P” peak at 1.983 eV corresponds to the peaks “3”, “4”, and “5” in FIG. 19a. The peaks denoted by “C/P” can be attributed to the cavity-enhanced hot luminescence assisted by lower density of states phonons;

FIG. 26 illustrates phonon and electronic dispersion of crystalline silicon. a, Phonon dispersion along with the dashed lines showing the phonon modes with high density of states (zero slopes) at three different momentum values (Adapted from S. Wei, “Phonon dispersion of silicon and germanium from first principles calculations, Phys. Rev. B 1994)). b, Electronic dispersion showing the corresponding energies at the same momentum values as high density phonons in a, which explain the observed strong hot luminescence bands (Dispersions Adapted from J. R. Chelikowsky, “Electronic structure of silicon,” Phys. Rev. B. 1974).

FIG. 27 illustrates FDTD calculated size-dependent absorption for plasmonic Si nanowires coupled with Ω-cavities under the laser excitation at a wavelength of 457.9 nm with the beam spot size of 2 μm, which is the same condition as the experiments. For the size range from 50 to 70 nm, the absorption was estimated to be ˜1%. As the diameter decreases, a resonance, which originates from dielectric antenna effect, shifts to the laser wavelength, giving rise to enhanced absorption at 40 nm. Note that the calculated absorption for 70 nm diameter photonic silicon nanowire without the plasmonic Ω-cavity is estimated to be ˜2%.

### DETAILED DESCRIPTION OF ILLUSTRATIVE EMBODIMENTS

The present invention may be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention. Also, as used in the specification including the appended claims, the singular forms “a,” “an,” and “the” include the plural, and reference to a particular numerical value includes at least that particular value, unless the context clearly dictates otherwise. The term “plurality” as used herein, means more than one. When a range of values is expressed, another embodiment includes from the one particular value and/or to the other particular value. Similarly, when values are expressed as approximations, by use of the antecedent “approximately,” “essentially,” or “about,” it will be understood that the particular value forms another embodiment. All ranges are inclusive and combinable, and any documents cited herein are incorporated by reference in their entireties for any and all purposes.

It is to be appreciated that certain features of the invention which are, for clarity, described herein in the context of separate embodiments, may also be provided in combination in a single embodiment. Conversely, various features of the invention that are, for brevity, described in the context of a single embodiment, may also be provided separately or in any subcombination. Further, references to values stated in ranges include each and every value within that range.

It should be understood that the term “diameter” is used in this disclosure to refer to a cross-sectional dimension of a nanowire, a nanowire core, or other feature. The term “diameter” is—in some places—used for the sake of convenience, as the disclosed devices need not be circular in cross-section. Accordingly, the term “diameter” should be understood to refer to a cross-sectional dimension of the component to which “diameter” refers and should not be understood as necessarily requiring a circular cross-section.

Plasmonic nanowires are a type of nanowire with increased emissions. With plasmonic nanowires the highly concentrated fields of plasmonic nanocavities are integrated with a core to completely alter the excited-state optical processes. In the embodiments discussed herein, either a direct or indirect bandgap material may be used in the core. By integrating the plasmonic nanocavities, emission from highly non-thermalized excitons are observed, indicating very high radiative rate enhancement.

It should be understood that the term “diameter” is used in this disclosure to refer to a cross-sectional dimension of a nanowire, a nanowire core, or other feature. The term “diameter” is—in some places—used for the sake of convenience, as the disclosed devices need not be circular in cross-section. Accordingly, the term “diameter” should be understood to refer to a cross-sectional dimension of the component to which “diameter” refers and should not be understood as necessarily requiring a circular cross-section.

Shown herein is the generation of dominant hot-exciton emission, which is to say, luminescence from non-thermalized excitons that are enhanced by the highly concentrated electromagnetic fields supported by the resonant whispering-gallery plasmonic nanocavities of nanowire devices. By tuning the plasmonic cavity size to match the whispering-gallery resonances, an almost complete transition from thermalized exciton to hot-exciton emission can be achieved, which reflects exceptionally high radiative rate enhancement of >10³ and subpicosecond lifetimes. Core-shell plasmonic nanowires are an ideal test bed for studying and controlling strong plasmon-exciton interaction at the nanoscale and opens new avenues for applications in ultrafast nanophotonic devices.

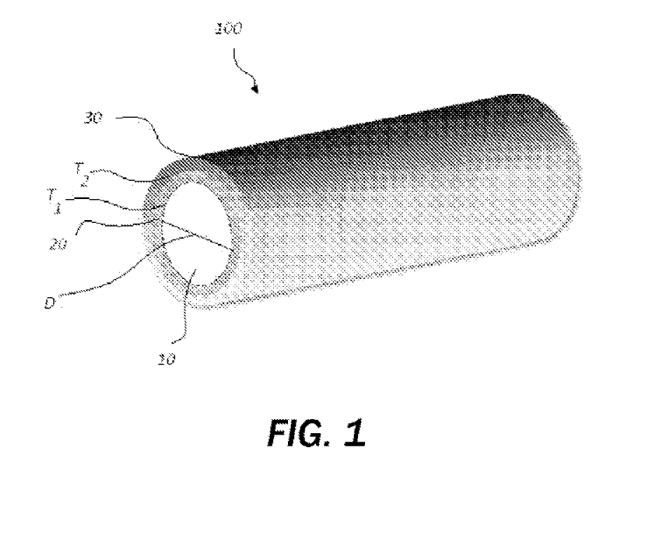

To modify the exciton relaxation and emission properties, a semiconductor nanowiredielectric metal core-shell plasmonic nanocavity structure was manufactured. An exemplary plasmonic nanowire 100 is shown in FIG. 1, comprising a core 10, an interlayer 20 and a shell 30.

The core 10 shown in FIG. 1 may be made from a direct bandgap material. In the exemplary embodiment shown the material is a CdS nanowire core 10. Other illustrative direct bandgap materials that may be used to form the core 10 include CdSe, CdTe, ZnO, ZnS, ZnSe, GaN, GaAs, InP, InAs, InN, CuO, PbS, PbSe, PbTe, and the like, or combinations thereof.

The core 10 (e.g., made of CdS) may operate as a source of semiconductor excitons. The core 10 has a cross-sectional dimension (e.g., diameter D) that may be between 20-200 nm, preferably between 50-150 nm, and even between about 10 nm to about 1 micrometer. The dimensions of the interlayer and metal shell may vary depending on the core's dimensions. For example, if the core is 10 nm, then the inter-layer may be 2-5 nm thick and the metal shell is suitably thicker than the diameter of the thickness of the core and interlayer.

The thickness of interlayer may be anywhere between about 5% to about 95% of a cross-sectional dimension of the core. Likewise, the thickness of the metal shell may be equal to the combined cross-sectional dimension of the core and the interlayer. The thickness of the metal shell may be equal to (or greater than) the thickness of the interlayer plus a cross-sectional dimension of the core. The thickness of the metal shell may also be equal to or greater than the total cross-sectional dimension of the core and interlayer.

The core (and associated layers) may have virtually any length that the user desires. Lengths of about 1, 5, 10, 50, 100, or even about 500 nm are all suitable. The core may also have a length of a micrometer, tens of micrometers, hundreds of micrometers, or even a length of millimeters, depending on the user's needs. Lengths of centimeters or greater are also considered suitable for the disclosed devices.

The diameter of core 10 may be larger or smaller than the foregoing ranges. The thickness of interlayer 20 may be selected so as to correspond to a whispering gallery resonant mode of the formed plasmonic nanocavity. Without being bound to any particular theory, the role of the interlayer is to prevent exciton quenching by the metal layer. The energy (or frequency) at which the whispering gallery mode (this is the surface plasmon mode) occurs is sensitive to the device geometry, which includes the diameter of the core, interlayer, and metal shell, but again. Controlling the energy of the whispering gallery mode is not necessarily the primary purpose of the interlayer. The diameter D of the core 10 may, in some embodiments, be referred to as the thickness of the nanowire.

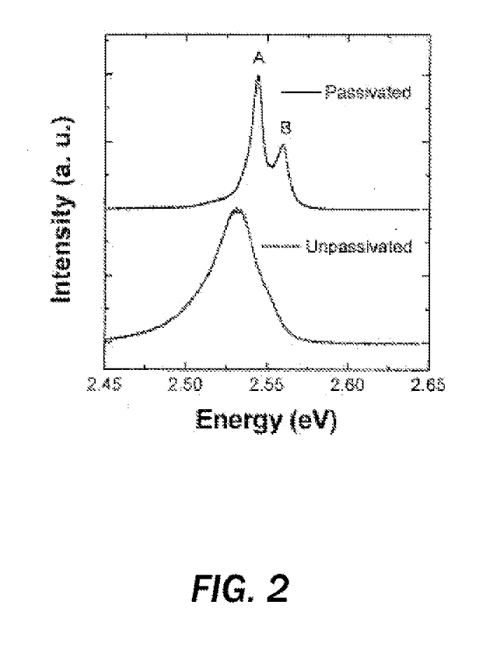

Suitably surrounding the core 10 is an interlayer 20, which in the embodiment shown in FIG. 1a is made of SiO₂. Other suitable materials for the interlayer 20 may include SiO₂, Si₃N₄, MaF₂, TiO₂, Al₂O₃, HfO₂ or MgO, and the like, or combinations thereof. The interlayer 20 plays two roles; first, it electronically passivates the surface defects of the nanowire core 10 (e.g., made from CdS) due to the formation of metal-sulphate bonds formed during atomic layer deposition. The passivation gives rise to predominantly free exciton emission from CdS, whereas the emission of unpassivated CdS nanowires is dominated by defect-related bound excitons. This can be seen in the graph in FIG. 2 where the photoluminescence spectra of a passivated structure with a 5 nm thick SiO₂ interlayer 20 and CdS nanowire core having a diameter, D=100 nm is shown. Also shown is the spectra for an unpassivated CdS nanowire core with a diameter of D=130 nm. The surface passivation results in the predominant free-exciton emission from photonic CdS nanowire cores.

The second role of the interlayer 20 is to retard or even prevent rapid quenching of excitons because of the metallic shell 30 (which may be made of Ag or other metal). A preferred thickness for an interlayer 20 in the embodiment shown is 5 nm. The thickness chosen is a compromise to prevent exciton quenching while ensuring strong interaction of plasmonic modes with the CdS core 10. The thickness T1 of the interlayer 20 may be in the range of from about 1 nm to about 10 nm or even 20 nm or even 50 nm. The thickness is preferably between 3-8 nm, and most preferably between 4-6 nm. The thickness of the interlayer 20 may be selected to correspond to a whispering gallery resonant mode of the formed plasmonic nanocavity.

The metallic shell 30 of the plasmonic nanowire 100 may be, for example, an Ag nanoshell, in the embodiment shown in FIG. 1. The metallic shell 30 supports plasmon cavity modes. A thickness T₂ of 15 nm for the Ag metallic shell 30 overcomes the challenges of coupling the light in and out through the metal layer while maintaining a good plasmonic cavity. The Ag metallic shell 30 may have a thickness T₂ ranging from 5-50 nm. Other materials for the shell 30 may be Ag, Au, Al, Pt, Cu, Pd, graphene, and the like, as well as combinations of these or other conductive materials. Metallic shell materials are considered especially suitable; materials that sustain surface plasmon resonance in the region of interest are considered especially suitable.

Structural and chemical analysis by energy-dispersive X-ray spectroscopy was used to confirm the conformal coating of SiO₂ and Ag. In evaluating the effect of the plasmonic cavity on the emission properties, 5 nm SiO₂-coated CdS nanowires without a Ag metallic shell were prepared.

Figures representing the layers would show transmission of an electron microscope image showing the SiO₂ layer on a CdS nanowire produced by atomic layer deposition, lines indicate the thickness of the SiO₂ interlayer 20; a transmission electron microscope micrograph of the fabricated CdS—SiO₂—Ag core-shell structure, with lines indicating the 15 nm Ag shell thickness and an elemental mapping image showing the highly conformal coating of SiO₂ and Ag on the CdS nanowire measured by energy-dispersive X-ray spectroscopy.

In fabricating the plasmonic nanowire 100, single crystalline CdS nanowires were grown on Si(100) substrates by an Au/Pd nanoparticle-catalyzed vapor-liquid-solid method using a quartz tube vacuum furnace. At a temperature of 760° C., pure CdS powder (99.999% Sigma Aldrich) was evaporated for 3 hours in an argon flow of 100 SCCM. The growth substrate was subsequently moved to an atomic layer deposition system (Cambridge Nanotech) to passivate the nanowires with a 5 nm SiO₂ layer by alternating O3, 3-Aminopropyltriethoxysilane (APTES), and H2O pulses at a temperature of 150 deg. C. A 15 nm Ag shell was conformally coated using an e-beam evaporator at a low deposition rate of 0.2 A/s.

Nanowires on growth substrates were dry-transferred onto 400 nm-thick SiO₂ coated Si substrates to carry out optical experiments using a home-built microscope equipped with a 60×, 0.7NA objective (Nikon) with a spatial resolution of 500 nm. A continuous wave argon-ion laser (Coherent), tuned at a wavelength of 457.9 nm, was focused to a beam spot size of 800 nm to pump individual nanowires on the sample at low excitation powers (<100 kW/cm²), thus avoiding heating of the samples. Photoluminescence spectra were collected using a spectrometer (Acton) and a cooled CCD (charge-coupled device) (Pixis 2K, Princeton Instruments) with a spectral resolution of 0.1 nm. Low-temperature and temperature-dependent measurements were conducted using a liquid nitrogen cooled cryostat (Janis Research). To avoid oxidation of the Ag shell, the samples were stored in vacuum.

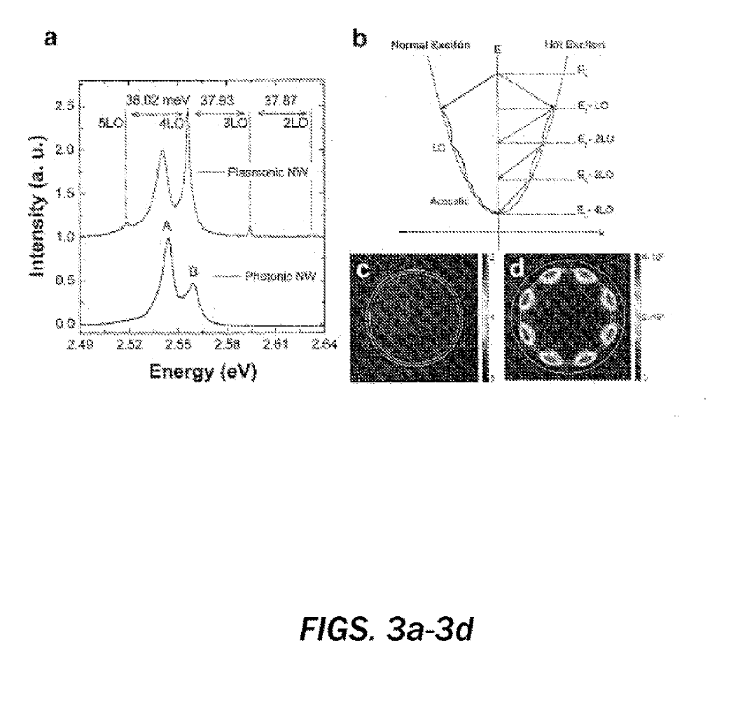

The optical properties of the plasmonic nanowire 100 and of the photonic nanowire (i.e. the structure without the metallic shell 30) were measured by means of microphotoluminescence carried out at 77 K for individual nanowires with the focused laser excitation energy of the 2.708 eV (457.9 nm) line of an Ar⁺ ion laser. The photoluminescence spectra of the photonic nanowires show emission from the recombination of free A- and B excitons of CdS, with peaks at 2.544 eV and 2.559 eV, respectively, this is shown in FIG. 3a (CdS core 10 diameter, D=115 nm). FIGS. 3a-f show hot-exciton emission from plasmonic and photonic nanowires. In FIG. 3a the photoluminescence spectra (at 77 K) of the photonic and plasmonic nanowire (NW) with core CdS diameters of 115 nm and 140 nm respectively is shown. Hotexciton emission lines, which appear as a progression, are indicated by nLO, where n is the number of participating LO phonons.

In FIG. 3b a schematic diagram of the exciton dispersion showing the relaxation and emission processes for the normal exciton and the hot-exciton emission, where EL is the energy of laser excitation is shown. In FIGS. 3c and 3d the calculated field distribution of the magnetic field intensity for the photonic (c) and plasmonic (d) nanowires (D=140 nm) at the 4LO energy of 2.556 eV is shown. The plasmonic nanowire shows a whispering-gallery plasmon cavity mode, which is absent for the photonic nanowire. Circles indicate the interfaces of the core-shell structure.

New narrow emission lines appear for the plasmonic nanowire 100 at an equidistant progression below the laser excitation energy, with separations corresponding to the energy of the CdS LO phonon of ˜38 meV, reflecting the modified spontaneous exciton emission (FIG. 3a, D=140 nm). These emission lines can be attributed to hot-exciton emission due to significant exciton radiative lifetime shortening, enabled by the coupling of the CdS nanowire to the plasmonic nanocavity with an enhanced electromagnetic field.

Another feature of the spectra of the plasmonic nanowire 100 is that the main peak now corresponds to the 4LO hot exciton, with significant line narrowing superimposed on the Bexciton position, indicating dominant emission from hot excitons. FIG. 3b schematically compares the thermalization of excitons (normal exciton) with the generation of hot-exciton emission with relaxation by LO-phonon scattering to the exciton (parabolic) and light-line dispersion (vertical) from which the emission is measured. Emission from the intermediate hotexciton states can be observed if the radiative decay rates become comparable to the LO-phonon scattering process, which is possible because of the large field enhancement from the plasmonic nanocavity.

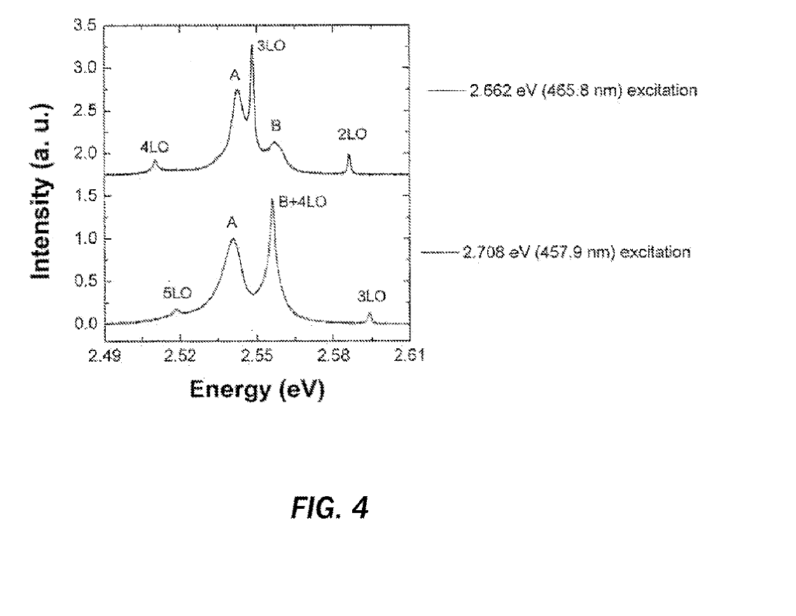

To further ensure that hot-exciton emission has been observed by LO-phonon coupling, plasmonic nanowire spectra were measured with a different laser excitation energy (2.662 eV). The resulting spectra confirmed that the spectral position of the LO progression is sensitive to the excitation energy. FIG. 4 is a graph that shows that the excitation energy dependence of hot-exciton emission spectra, showing different hot-exciton peak positions under 2.662 eV and 2.708 eV laser excitation. CdS core 10 diameters D of the plasmonic nanowires are 130 nm and 140 nm for upper (2.662 eV) and lower (2.708 eV) spectra, respectively.

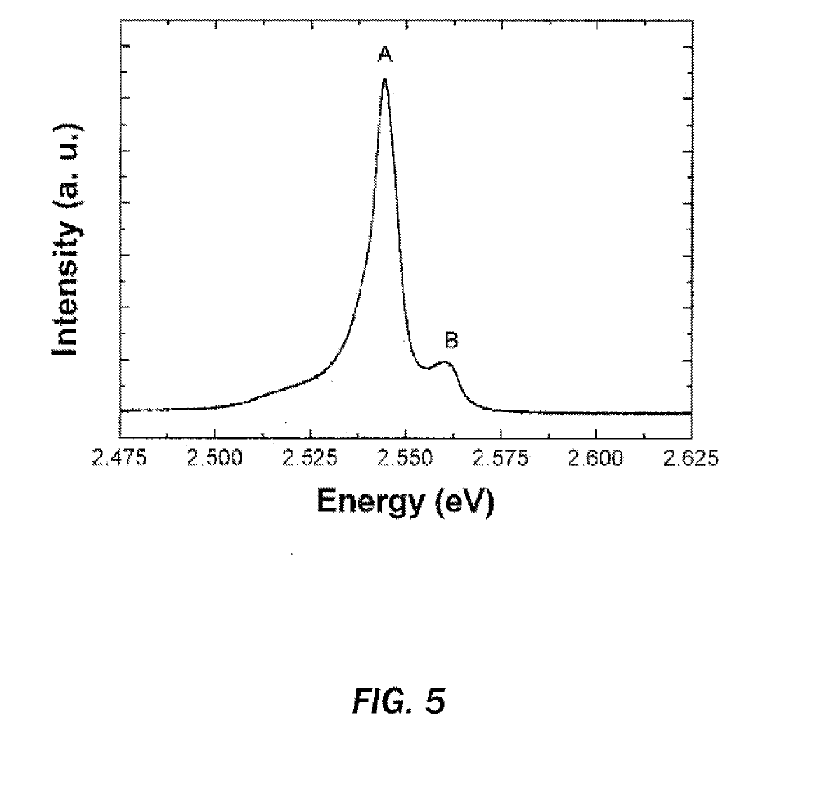

No hot-exciton peaks were observed for SiOrcoated CdS nanowires on planar Ag films. Without being bound to any single theory, this suggests that a plasmonic nanocavity supports the large field enhancements needed to observe emission from non-thermalized excitons. This is shown in FIG. 5, which shows the photoluminescence spectrum of a 5 nm SiO₂ coated nanowire (D=165 nm) on a planar Ag film, showing no hot exciton peaks for the planar structure. Note that the B-exciton peak is lower than expected due to the anisotropy the B-exciton couples to the waveguiding emission while A-exciton emission does not.

In FIG. 2, the nanowire diameter was smaller than the critical size required for efficient waveguiding and hence shows the correct ratio of A and B exciton peaks. Significant shortening of the lifetime of the excited state, from 1,600 ps for photonic nanowires to 7 ps for the plasmonic nanowire 100, is directly observed by time-resolved photoluminescence measurements performed on an ensemble of 300-500 nanowires (average CdS core 10 diameter d1 of, 140±50 nm) at room temperature, the results of which are shown in FIGS. 3e and 3f. The shortening of the lifetime of the excited state for the plasmonic system also suggests the change in the dynamics of the excited state due to the large field enhancements in comparison to the photonic wires. The hot-exciton emission phenomena and resonance Raman scattering peaks both occur at phonon progressions from the excitation laser, but they originate from different physical phenomena.

The differences may arise—again without being bound to any single theory—to whether the process requires the participation of real exciton states (hot-exciton emission) or not (resonance Raman scattering). FIG. 3a shows that with a non-thermalized emission from plasmonic nanowires, the peak separation increases with higher order LO peaks. In FIG. 3b, for hot-exciton emission, the higher order processes require LO phonons with lower k values to satisfy momentum conservation. In wurtzite CdS crystals, the energy of the LO phonon decreases as the momentum increases from the r point. Thus, the higher order hot-exciton process should involve LO phonons with lower momentum values (hence higher energies) and result in a larger separation, as observed. On the other hand, resonant Raman processes involve phonons from an extremely small range of k values close to the almost vertical light line, and typically shows progressions at very similar energies.

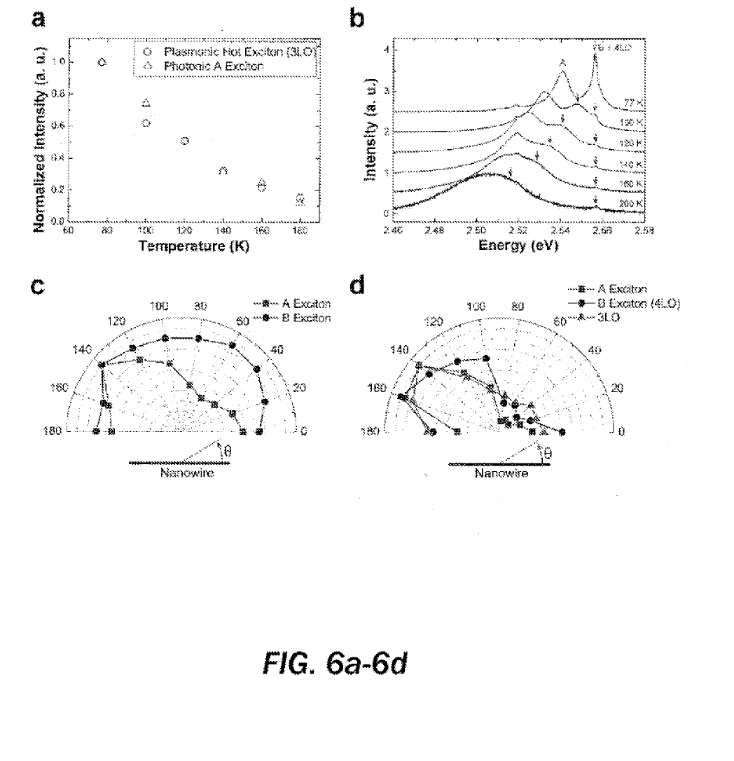

Further studies of the temperature and polarization dependent properties of the hotexciton peaks were conducted. At higher temperatures, a pronounced quenching of the emission intensity is expected for the hot exciton because of the increased nonradiative decay rate, whereas the resonance Raman scattering intensity is not very sensitive to the temperature. As shown in FIG. 6a, significant thermal quenching of the hot-exciton intensity is observed, with a quenching rate similar to the A-exciton, where the intensity of the hot exciton and the A-exciton were measured from the plasmonic and the photonic nanowires, respectively. FIG. 6a shows temperature-dependent quenching of the emission intensity for the hot exciton (3LO peaks) and free A-exciton, which are measured for the plasmonic (d=140 nm) and photonic (d=150 nm) nanowires, respectively. The intensities are normalized to the values obtained at 77 K for each nanowire.

Furthermore, with increasing temperature, the enhanced emission intensity of the 4LO hot exciton, which is in resonance with the B-exciton level at 77 K, is drastically decreased because the B-exciton energy shifts whereas the 4LO peak does not, as shown in FIG. 6b. The enhanced 4LO hot-exciton emission resonant with the B-exciton at 77 K, shown in FIG. 3a is attributed to the rapid accumulation of the hot-exciton population at the B-exciton ground state, as excitons at the lowest energy level do not relax further and can radiatively decay directly from k˜0 states.

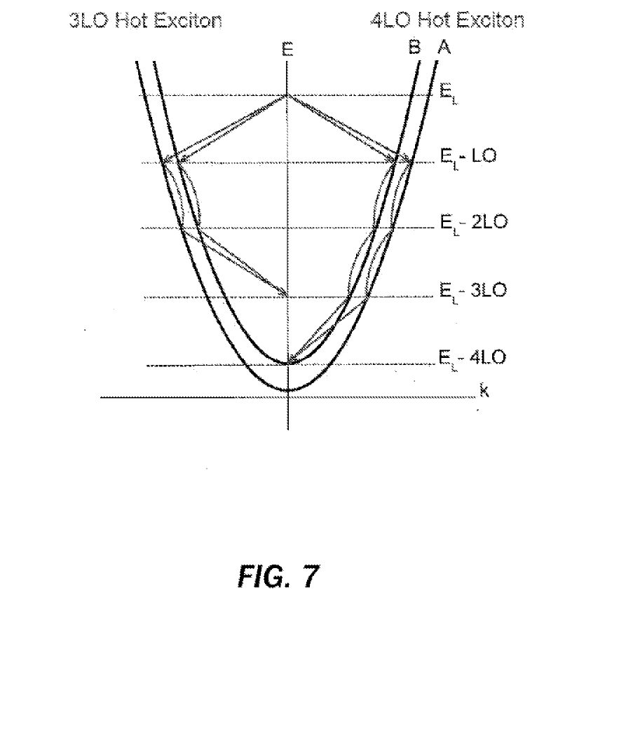

The hot-exciton emission feature can also be inferred from the polarization properties of plasmonic nanowires. The polarization of hot-exciton peaks should be similar to CdS excitons (A and/or B), whereas that of Raman scattering should follow the pump laser polarization. For CdS crystals, the A-exciton is linearly polarized perpendicular to the c axis and the B-exciton is isotropic, which is consistent with the measurements for the photonic nanowires shown in FIG. 6c. Interestingly, for plasmonic wires, the polarization of hot-exciton peaks becomes predominantly linearly polarized, with the polarization direction matching that of the A-exciton, but with a lower anisotropy than that of the A-excitons, see FIG. 6d. Therefore, the hot-exciton emission has the polarization characteristics of both the excitons, leading to the linear polarization (a combination of linear A-exciton and isotropic B-exciton polarizations). As a result of the reduced radiative lifetime, emission of hot excitons originates from both the A- and B-exciton dispersions by LO-phonon-assisted photon emission. This is shown in FIG. 7, where a schematic diagram of the A and B exciton dispersions showing 3 LO and 4 LO hot exciton emission from both the A and B exciton dispersion by LO phono assisted photon emission processes.

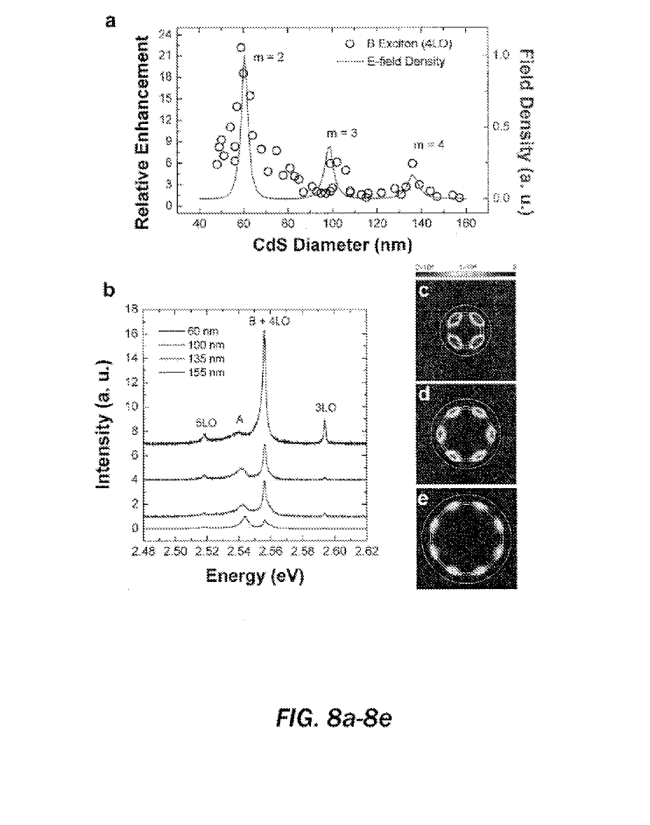

To study the effect of the plasmon nanocavity size on the hot-exciton emission, a series of photoluminescence measurements were performed on 44 plasmonic nanowires ranging from 48 to 157 nm in diameter. As the B-exciton peak is strongly modified by the resonance with the 4LO hot exciton in plasmonic nanowires, shown in FIG. 3a. An estimate of the 4LO hotexciton peak enhancements was obtained by first normalizing all the spectra at the A-exciton peak, and then measuring any increase in the B-exciton peaks above their values expected from the photonic nanowire. The estimated size-dependent enhancements shown in FIGS. 5a and 8b do not show a monotonic increase with decreasing size, but show a series of peaks at sizes of the core 10 of 60, 100 and 135 nm, reaching a highest value of 22 for the 60 nm plasmonic nanowire. The corresponding spectra for these three plasmonic nanowires are shown in FIG. 8b, along with that for the 155 nm wire, and show a large enhancement of the hot-exciton peaks compared with the non-resonant 155 nm wire case, shown in FIG. 8b.

The 60 nm wire shows very intense 3LO and 4LO peaks, which overwhelm the normal A-exciton emission, indicating an almost complete transition from the thermalized exciton to the hot-exciton emission. Taking into account the fast, sub-picosecond relaxation time of the LO phonons, it is evident that the modified radiative decay time must become comparable to the relaxation time of the LO phonons. Using simple kinetic modeling based on exciton kinetic energy relaxation, the modified radiative decay time due to the plasmonic cavity was estimated to be sub-picosecond for 60 nm wires, a marked reduction by more than three orders of magnitude from >1 ns for photonic nanowires. Furthermore, size-dependent enhancements with a series of peaks suggest a strong role played by the whispering-gallery plasmon cavity modes in the emission process.

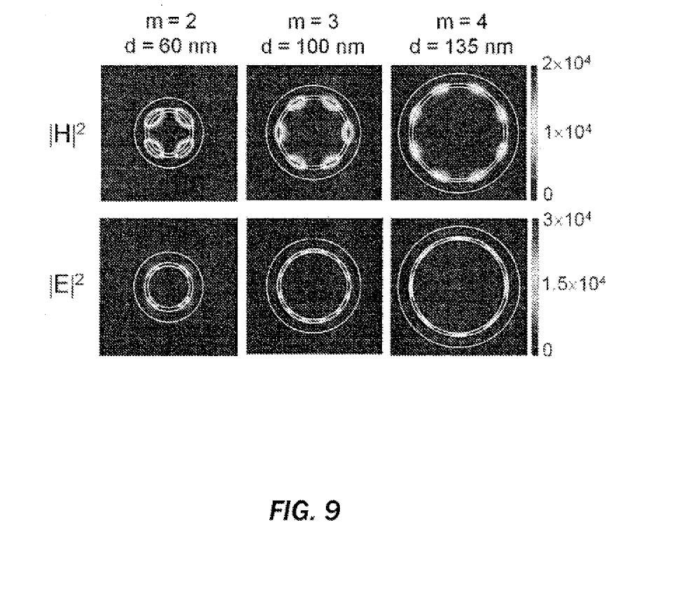

To investigate the origin and effect of field enhancement in the plasmonic cavities due to the excitation of the surface-plasmon modes on exciting the CdS core with the laser, numerical simulations were performed to calculate the field confinement for photonic and plasmonic nanowires at the 4LO hot-exciton energy. From the calculations, it was observed that, for sub-150 nm cores 10 of CdS, the plasmonic nanowires 100 supported whispering-gallery modes, shown in FIG. 3d, D=140 nm, m=4, but slightly off resonance. These modes are absent for photonic nanowires, shown in FIG. 3c, with a D=140 nm core. The azimuthal mode number, m, indicates the effective number of wavelengths around the inner circumference of the Ag shell 30. Calculations also confirmed that these nanowires (>1 micrometer) cannot support a waveguide cavity mode propagating along the long axis of the wire. This is consistent with the observation of the absence of end emission for all the plasmonic nanowires that were measured. As electric fields parallel to the plane of nanowire cross-section can excite the Plasmon whispering-gallery modes, the eigenmodes have magnetic fields perpendicular to the plane. This is shown in FIG. 9 where the calculated field distribution of the magnetic field intensity (the upper three images) and the electric field intensity (the lower three images for the resonance modes, m=2 (D=60 nm), m=3, (D=100 nm) and m=4 (D=135 nm). The white circles indicate the interfaces of the CdS core 10, the SiO₂ interlayer 20 and the AG shell 30.

Numerical calculations reveal that the enhancement in the electric field intensity for the 60 nm plasmonic nanowire 100, which supports the m=2 resonance mode with a cavity quality factor of 55, is as large as 40,000 in comparison with the same sized photonic nanowire as shown in 8d, for m=3, FIG. 8d, d=100 nm and m=4, FIG. 8e, d=135 nm resonance modes, the calculated field enhancement is 14,400 and 6,400, respectively, whereas it is as low as 200 for the non-resonant plasmonic nanowire with d=155 nm. Therefore, the observed hot-exciton emission peaks result from significant radiative lifetime shortening by the Purcell effect, which is the enhancement of the spontaneous emission rate by the resonant cavity electromagnetic fields. For the 60 nm plasmonic nanowire, the Purcell enhancement factor was estimated to be 3:8×10³, which is also consistent with the modeling.

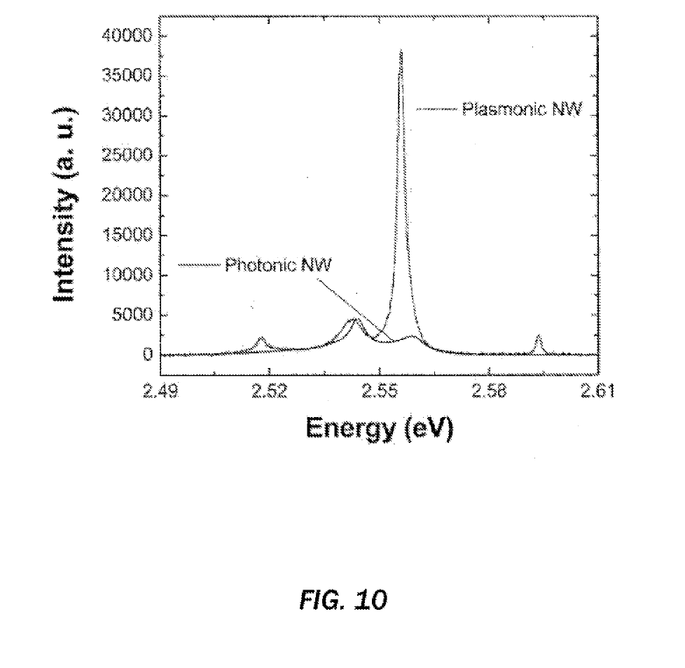

Taking into account the effects of coupling the light in and out through the Ag shell 30, by full 3D numerical calculations, a direct comparison of the spectra (photon counts) between a 60 nm plasmonic and photonic nanowire, shown in FIG. 10 shows that the intensities of the hot-exciton peaks are significantly enhanced in the plasmonic system. FIG. 10 shows the photoluminescent intensity between the plasmonic and photonic nanowires (60 nm CdS diameter for both cases) with taking into account the in and out-coupling of light through the Ag shell of the plasmonic nanowire. The in-coupling at laser excitation wavelength and the out-coupling at emission wavelength in the plasmonic nanowire with respect to the photonic nanowire was calculated to be 280% (enhancement) and 5% (reduction) respectively. Overall, a significant enhancement in the photon counts for the plasmonic system is observed.

This, combined with the shorter excited state lifetime for the plasmonic system suggests large radiative rate enhancements. As the excited-state lifetime of the plasmonic nanowires with an average size of 140±50 nm is measured to be 7 ps, it is estimated that the 60 nm plasmonic wire with a strong whispering-gallery resonance mode should have a subpicosecond lifetime, as a result of the ˜10 times enhancement observed for this nanowire size in comparison with the 140 nm sized wires shown in FIG. 8a.

The estimated sub-picosecond lifetime of the 60 nm plasmonic nanowire is also consistent with the Purcell factor calculations predicting an enhancement of 3.8×10³. The calculated size dependence of the field density inside the plasmonic cavity, shown in FIG. 4a, correctly reproduces the peaks in the experimentally determined enhancements, which clearly elucidates the critical role played by whispering-gallery plasmonic nanocavity resonances in influencing the relaxation process. In contrast, because of the larger optical wavelengths and lower confinement, the photonic wires show whispering-gallery modes with lower quality factor (20-30) in the exciton emission region for sizes greater than 280 nm, with the calculated Purcell enhancement factors of ˜10.

While the above discussion involved the plasmonic nanowire 100 with a direct bandgap material used in the core 10. Another embodiment of the present invention involves using an indirect band-gap material in the core in order to generate efficient light emission in the nanowire by using plasmon nanocavity structures.

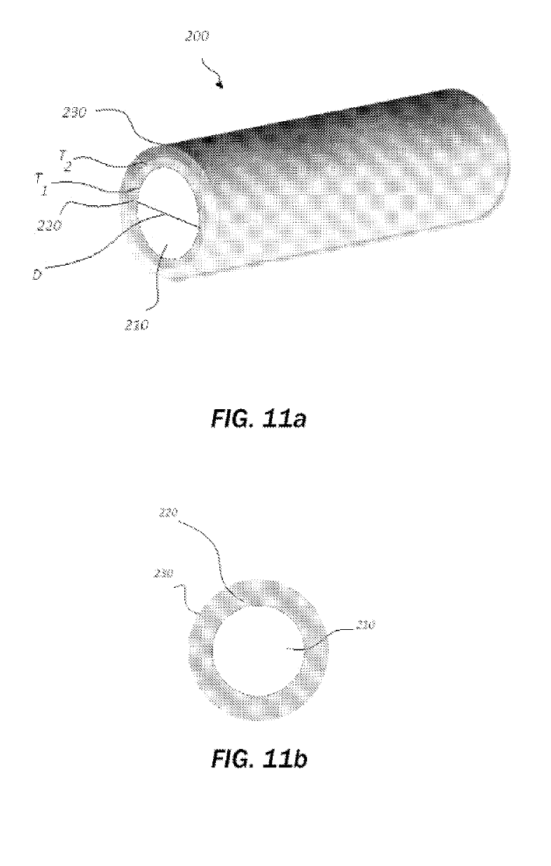

Indirect bandgap material include, for example, Si, Ge, Si—Ge, SiC, GaP, and the like, as some non-exhaustive examples. Other light-emitting, or potentially light-emitting materials are also suitable core materials. The indirect bandgap plasmonic nanowire 200 is a light-emitting device that comprises a semiconductor nanowire-dielectric-metal core-shell plasmonic nanocavity structure. The structure comprises a semiconductor nanowire of any indirect bandgap material used as the core 210 of the plasmonic nanowire 200. The core 210 is a source of electron-hole pairs (excitons). The plasmonic nanowire 200 further comprises an interlayer 220 made of any dielectric/insulating material. For example, the interlayer 220 may be SiO₂. The plasmonic nanowire 200 may further comprise a metallic shell 230. The metallic shell 230 supports the plasmon cavity modes. FIGS. 11a-11b show the plasmonic nanowire 200.

Similar to the interlayer 20 discussed above, the insulating interlayer 220 plays two roles; it electronically passivates the surface defects of the semiconductor nanowire core 210 to remove nonradiative recombination sites on the nanowire surface. The second role of the insulating interlayer 220 is the prevention of rapid quenching of electron-hole pairs due to the metallic shell 230. An optimal thickness of the insulating interlayer 220 may be a few nanometers (2-5 nm) which are a good compromise for preventing electron-hole pair quenching but ensuring strong interaction of plasmonic modes with the semiconductor core.

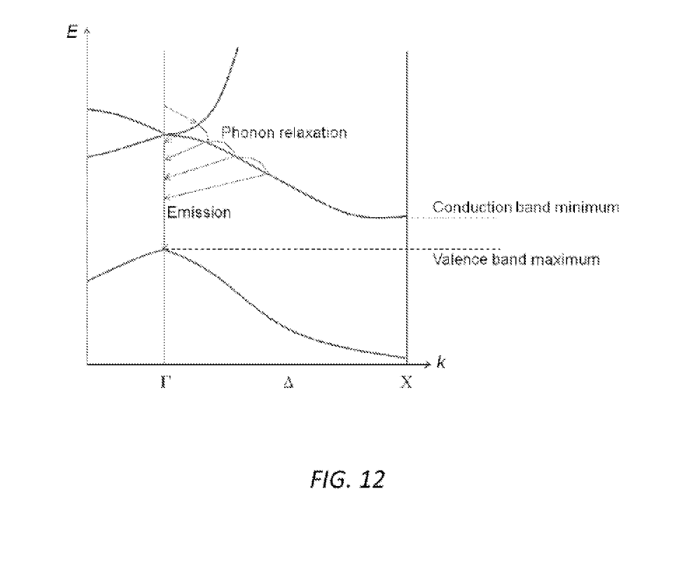

In indirect bandgap semiconductors such as silicon, the radiative lifetime of electronhole pair is typically in the millisecond range, which is much longer than that of direct bandgap materials because the momentum mismatch between electrons and holes in the conduction and the valence bands extrema is extremely large. As shown in FIG. 12, upon excitation using light or by carrier injection, the excited carriers (electrons) in an indirect bandgap material start to relax in the conduction band due to interaction with phonons (optical phonons with picoseconds timescale followed by acoustic phonons with ˜100 ps timescale) and eventually end up at a minimum position in energy by losing excess energy to phonons, but with momentum values which are very high in comparison to holes in the valence band. Due to this momentum mismatch between the electrons and holes, their recombination becomes less likely and extremely slow, and their recombination typically results in heat generation rather than emission of light. However, if in an indirect bandgap material, very intense electromagnetic fields can be created, then the timescale of electron-hole recombination can be made faster and comparable to the interaction with optical phonons, avoiding relaxation of electrons to different momentum value positions, resulting in emission of light upon electron-hole recombination.

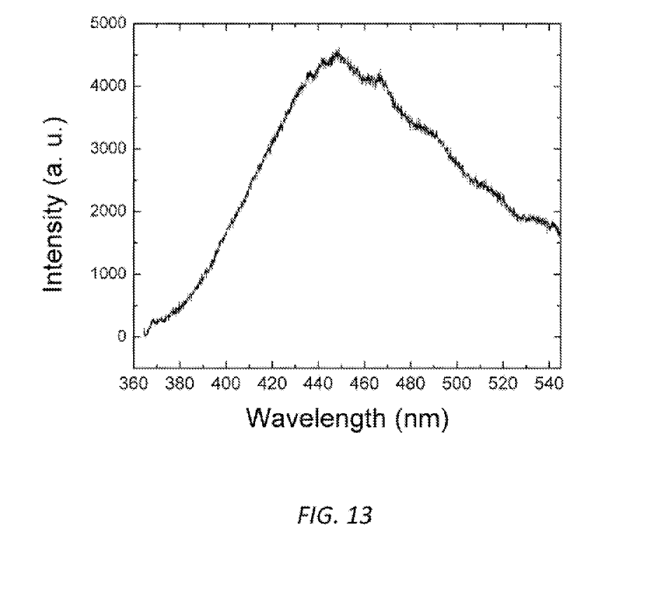

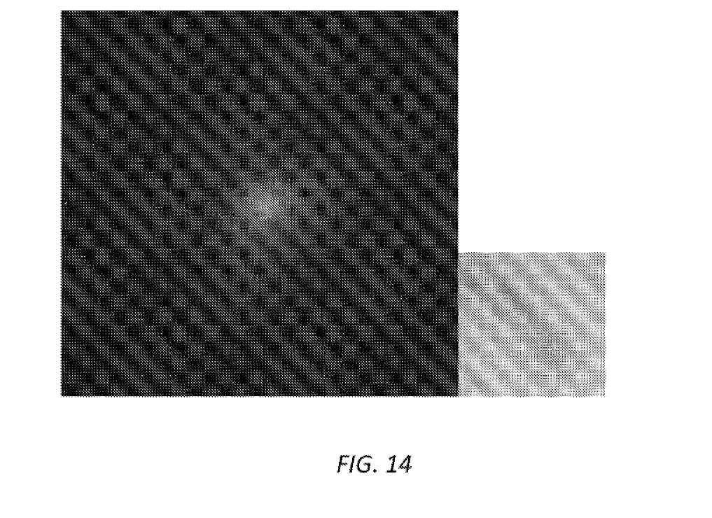

The plasmonic nanowire 200 of the present invention may generate very intense electromagnetic fields due to the plasmon nanocavity (by surface plasmons). The plasmonic nanowire 200 can produce radiative recombination from hot carriers (high-energy electron-hole pairs) in the indirect bandgap semiconductor nanowire core 210, which results in efficient light emission from excited states before the relaxation of hot carriers by emitting optical phonons. The strongly enhanced electromagnetic field inside the plasmon nanocavity dramatically shortens the radiative lifetime to a sub-picosecond, which is comparable with the relaxation time so that the sub-picosecond lifetime gives rise to UV-VIS light emission from indirect bandgap bulk silicons, shown in FIGS. 13 and 14.

Even at room temperature, the plasmonic nanowire 200 emitted an efficient bluegreen light emission. The experiments demonstrate that the plasmonic nanowire 200 can obtain light emission from Si and other indirect bandgap materials.

As the current silicon-based electronics has faced limitations on the speed for data processing due to the inherent issues of RC time delay and Joule heating, silicon optoelectronics, which can provide ultrafast optical data processing on a silicon microchip, has been intensively studied by many researchers both in academia and industry.

One challenge has been to obtain light emission from Si, which is not possible due to the low emission efficiency in indirect bandgap materials due to momentum mismatch. Also, integration of direct bandgap materials which emit light efficiently on Si substrates has been challenging due to the mismatch in their crystal structures. Light emission from nanocrystalline and nanoporous silicon has been reported and researched extensively; however, the efficiency is low and these structures are not amenable for the fabrication of electrical injection devices. Therefore, it is desirable to develop device technologies for efficient emission of light from silicon and other indirect bandgap materials which are also compatible with electrical injection devices.

One may use nanoscale silicon structures (not necessarily quantum confined length scales, i.e., <5 nm). These can be made in efficient electrical injection devices and hence can be used as a monolithically integrated light source on optically interconnected silicon microchips for ultrafast data processing.

As another application, the silicon light emitting device can be exploited as an optical probe for optical bio-sensors integrated on a silicon chip, of which the advantages are the compatibility with well-developed silicon technologies and the low manufacturing cost.

For the last two decades, it has been known that a light emission from silicon at a moderate quantum yield can only be possible when the silicon has a form of quantum confined structures such as porous silicon and silicon quantum dot. Since the exciton Bohr radius in silicon is about 5 nm, a tiny structure smaller than 5 nm would be required to obtain the light emission from indirect bandgap materials such as silicon and germanium, but it is still very difficult to fabricate the quantum confined structures with control over their size and properties, and then to be able to electrically connect them.

The indirect-gap light emitting device of this invention does not require a quantum confined nanostructure, but a semiconductor nanowire with the dimension of a few ten to a few hundred nanometers which can be easily fabricated at high precision using current top-down or bottom-up fabrication technologies. In addition, the size-scale of the present invention is compatible with efficient electrical injection devices, unlike quantum dots or nanoporous silicon.

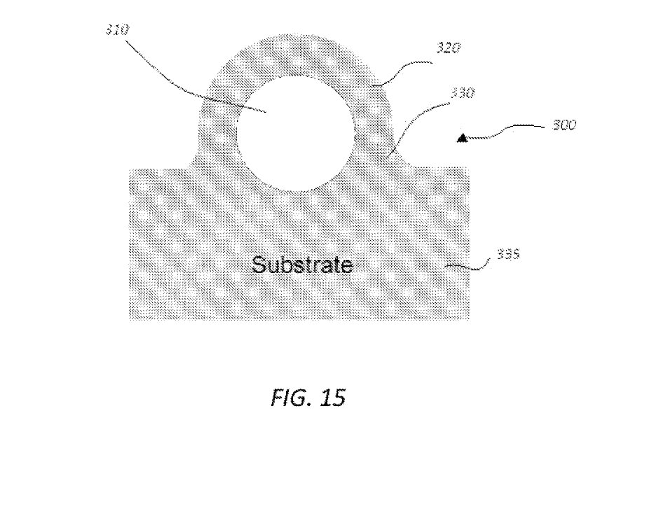

FIG. 15 shows an alternative embodiment of plasmonic nanowire 300 that is omega shaped. The plasmonic nanowire 300 comprises a core 310 made of indirect band gap material, although direct bandgap material may also be used. The plasmonic nanowire 300 further has an interlayer 320 made of dielectric insulating material and a metallic shell 330. Additionally there is a substrate 335, that may be made of any commercially effective material. The plasmonic nanowire 300 has higher out-coupling and is compatible with Si devices fabricated commercially. An omega shaped device may, in some cases, have lower outcoupling. The omega shaped plasmonic nanowire 300 may further permit the metallic shell 330 to be thicker than otherwise effective.

The plasmonic nanowires disclosed herein (which may feature whispering gallery, Fabry-Perot modes or both, depending on configuration) can alter the radiative decay rates of excitons as a result of resonances with highly concentrated optical fields. The observation of the complete transition to non-thermalized exciton emission demonstrates that the spontaneous emission properties of semiconductors can be tuned over a very wide range with ultra-small mode volume plasmon nanocavities in spite of their low quality factors. The tunability of the excited state relaxation processes may open up novel ways to develop new device concepts for high performance deep-subwavelength optoelectronic devices that can be modulated at very high frequencies owing to the significantly shortened excited-state lifetime.

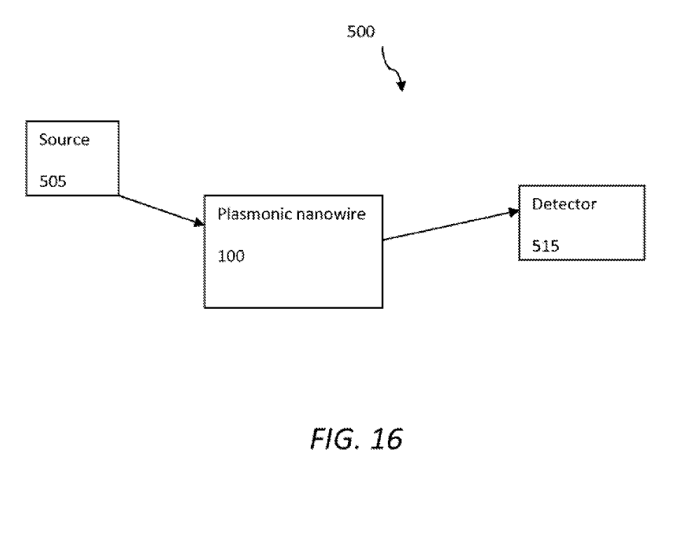

FIG. 16 shows an emitter device 500 in which the any one of the plasmonic nanowires discussed above may be employed. The source 505 may be a laser, such as the Ar+ ion laser that is able to excite the core 10 of the nanowire 100. The core may be excited by 2.662 eV or 2.708 eV laser excitation 2.662 or other sources. The emission may then be detected by a detector 515.

Additional Discussion

In bulk silicon, emission from hot-carriers (non-thermalized carrier recombination) has been observed by injecting carriers at large applied bias using a scanning tunneling microscope¹⁰, but the measured quantum efficiency is extremely low because of much faster hot-carrier relaxation time (intra-band; 0.1-1 ps) in comparison to the long radiative lifetime¹¹⁻¹³. Since the reported radiative lifetime for hot luminescence in bulk silicon is ˜10 ns at the Γ point,¹⁴ and the hot-carrier relaxation time is <1 ps,^{12, 13} the efficiency for hot luminescence across the direct band-gap is expected to be ˜10⁻⁴ at the Γ point. Furthermore, as hot-carriers relax, the radiative lifetime would increase due to the involvement of phonons in emission processes, resulting in lower quantum efficiencies. However, visible light emission from hot-carriers in “bulk” silicon can be efficient if the radiative lifetime becomes comparable with the hot-carrier relaxation time. In addition, enhanced emission from hot-carriers in silicon can enable studies of photophysics of indirect bandgap materials, which is otherwise challenging due to low emission quantum yields. Although silicon photonic crystal nanocavities have recently demonstrated enhancements up to 100, the emission was mostly generated from thermalized carriers in the near-infrared wavelength range.^{15,16}.

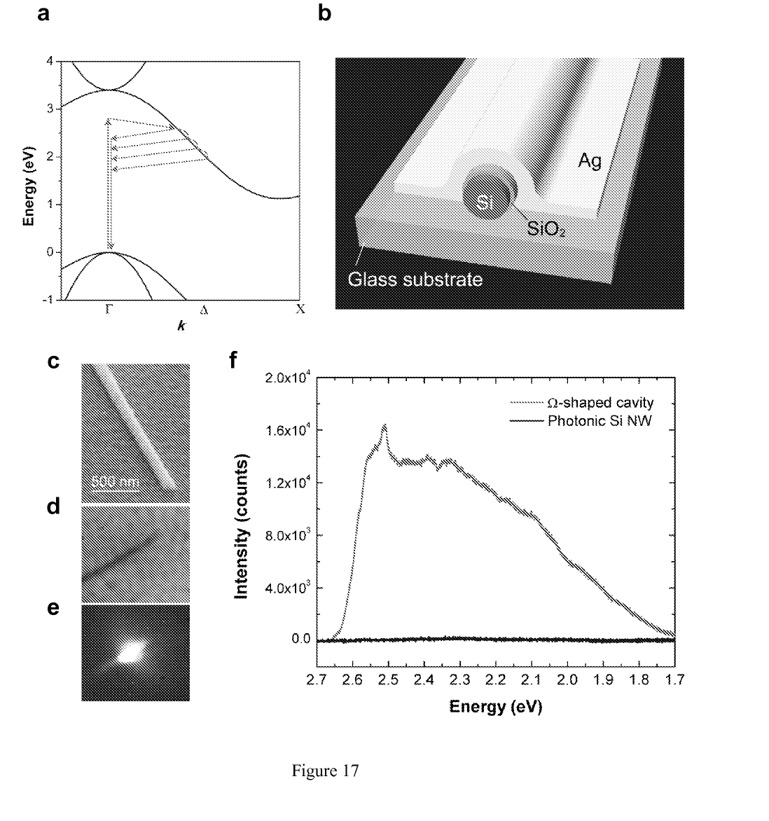

Provided here is light emission with a high quantum yield (>1%) at room temperature from “bulk-sized” (no quantum confinement; >30 nm) silicon (as one example) integrated with a plasmonic nanocavity via Purcell enhancement effect^{17,18}. Highly concentrated electromagnetic fields inside plasmon nanocavities induce phonon-assisted light emission from hot-carriers before their thermalization to the lowest energy state (near X-point) in the conduction band (FIG. 17a). The interaction of charged carriers with phonons and size-tunable nanocavity plasmons presents new ways to modulate the emission efficiency in silicon devices in the visible range.

To generate light emission from hot-carriers, one may fabricate the plasmonic nanocavity on single silicon nanowires (30-80 nm diameter range) by depositing a 5 nm SiO₂ interlayer (to prevent recombination of carriers at the metal surface while maintaining strong nanocavity plasmon fields in silicon), followed by a 100 nm-thick silver Ω-shaped cavity (see description elsewhere herein) to support surface plasmon polariton modes (FIGS. 17b to 17d). As shown in FIG. 17b, a nanowire (core, interlayer, and shell) may be disposed atop a substrate, such as glass and other non-metallic materials.

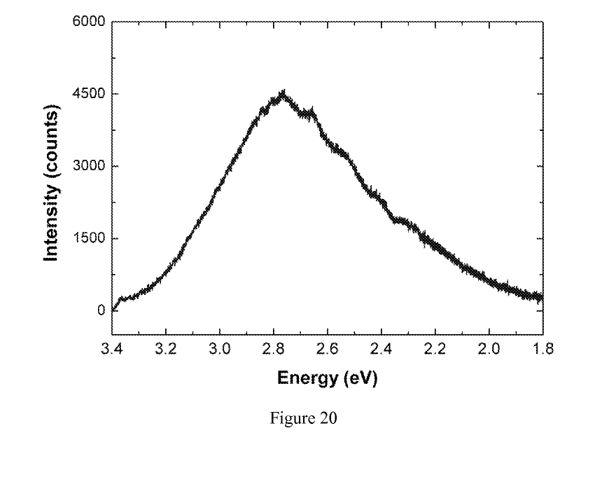

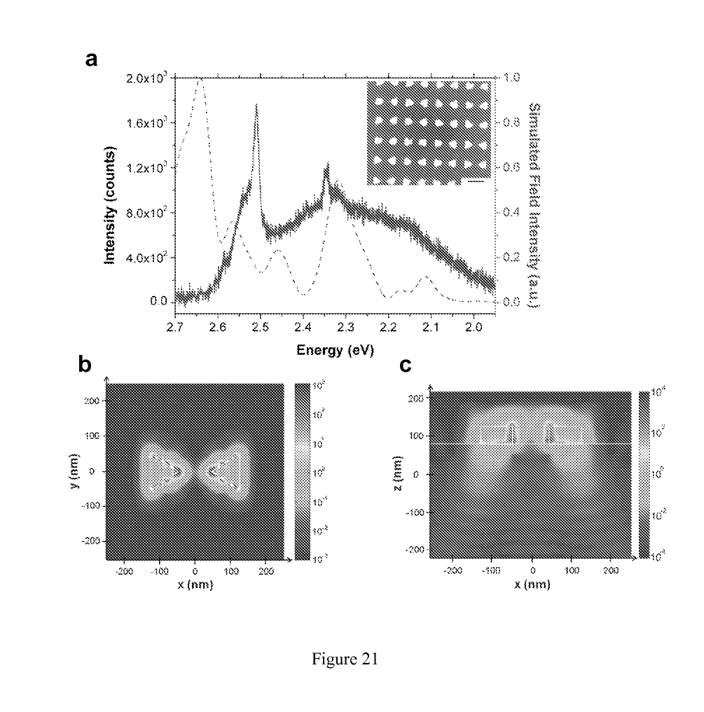

Room temperature micro-photoluminescence measurements were carried out on individual nanowire devices with an Ar⁺ laser excitation source (2.708 eV). Bright visible light emission was observed from single-plasmonic silicon nanowires (FIG. 17e). Because hot-carrier emission competes with intra-band relaxation, a broad hot luminescence band is expected ranging between the laser excitation and the indirect band-gap energy in silicon. FIG. 17f shows broad band hot luminescence spectra with high counts obtained from a single silicon nanowire coupled with the Ω-shaped cavity (Si diameter, d=65 nm), while no observable photon counts were detected from 5 nm SiO₂ coated silicon nanowires (d=60 nm) without the silver nanocavity where the length of silicon nanowires was typically 10 μm. Furthermore, under UV laser excitation at 3.486 eV, the hot luminescence band was observed to extend to the laser excitation energy, resulting in a broad UV to visible light emission (FIG. 20). These observations suggest that the hot-carriers emit photons through a phonon-assisted recombination process during intra-band relaxation. Furthermore, in order to test the generality of visible hot luminescence in plasmonically-coupled silicon, experiments were performed on planar silicon patterned with Ag bowtie structures (FIG. 21), confirming a similar spectrum as that of a plasmonic Si nanowires with hot luminescence bands. A bow-tie (or other structure) may comprise a semiconductor (e.g., silicon), an interlayer (e.g., SiO₂), and a metal (e.g., silver), but may have a configuration more like a sandwich than a core-shell structure. Other configurations are suitable, as bow-ties are illustrative only.

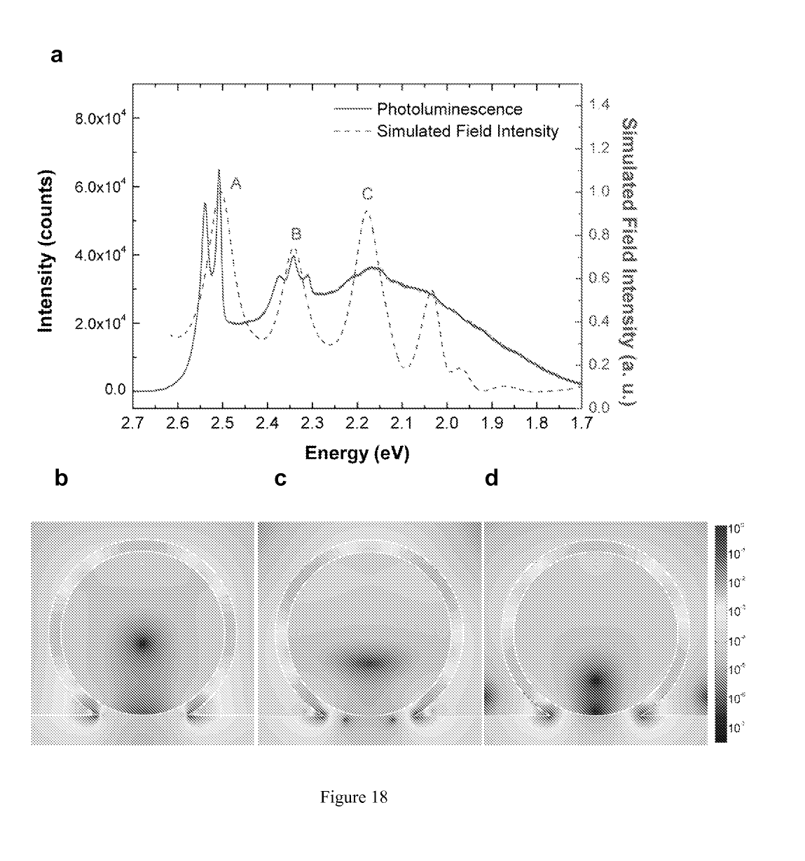

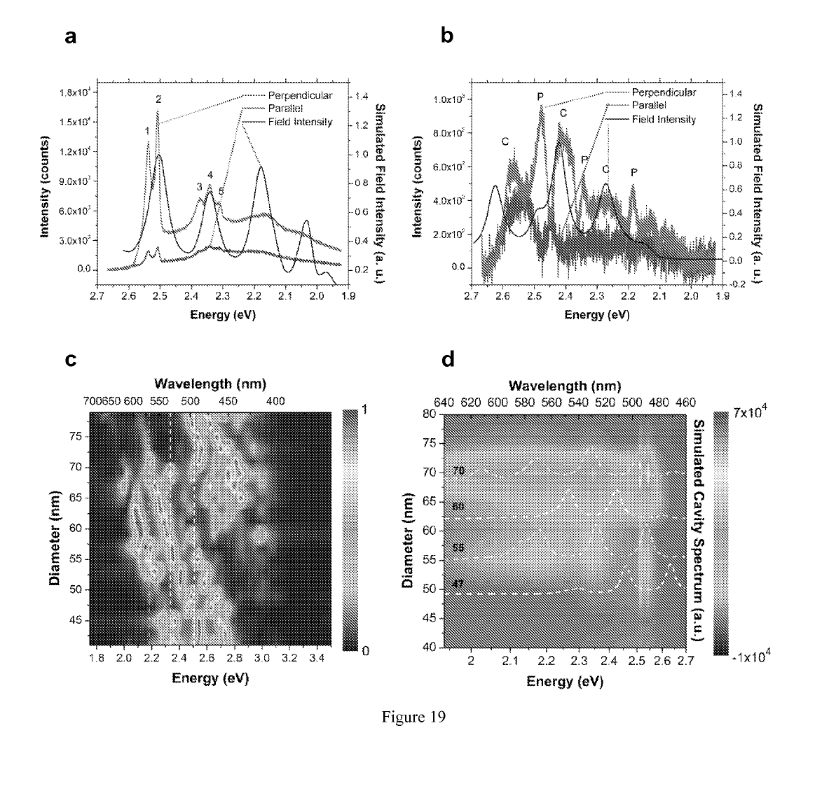

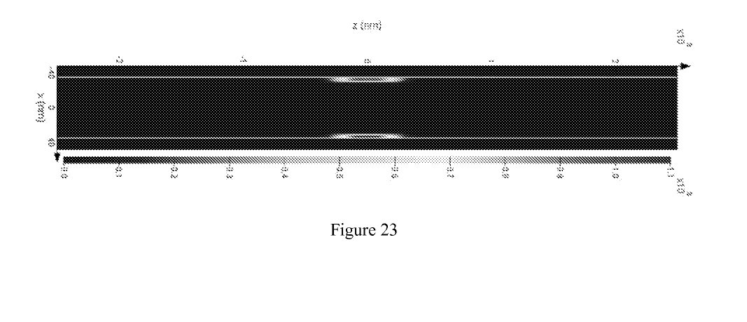

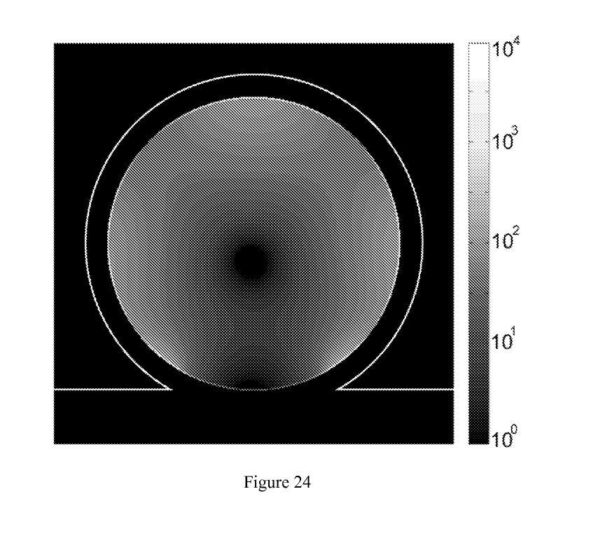

To further study the effect of size-tunable plasmonic nanocavity resonances on hot luminescence, various-sized silicon nanowires (d, 30 to 80 nm) coupled with an Ω-shaped cavity were examined. The intensity of hot luminescence band (integrated counts) reached a maximum at a resonant size (d=70 nm), with a clear peak structure reflecting phonon-assisted hot luminescence processes (FIG. 18a). To study the corresponding electromagnetic field distribution and the nanocavity Purcell enhancement, numerical simulations were performed for the Ω-shaped devices (see Methods). The simulated frequency-dependent electromagnetic field intensity inside the cavity (d=70 nm) correctly reproduces the resonance peaks observed in the hot luminescence spectrum (FIG. 18a). However, the observed photoluminescence spectrum shows more structure, which is related to the complex phonon-related carrier relaxation channels (discussed elsewhere). Simulations further reveal a plasmonic cavity mode along the Ag/SiO₂ interface perpendicular to the nanowire's long axis, as shown in FIGS. 18b-d calculated at 2.505, 2.342 eV, and 2.179 eV. Waveguide modes propagating along the long axis cannot be supported in the plasmonic nanowires because of the high propagation losses (10 to 30 dB/μm)¹⁷, which have been confirmed by three-dimensional simulations showing a confined cavity mode in the cross-sectional plane perpendicular to the wire axis (FIG. 23). For the highly confined plasmonic cavity modes, the quality factor was estimated to be ˜30 along with an ultrasmall mode volume of λ³/10⁴ (λ, free space wavelength), giving rise to a large radiative rate enhancement with Purcell factor >10³ at 2.505 eV (see Methods). In addition, calculated map of position-dependent Purcell factor shows enhancement of ˜10³ (within <5 nm from the Si surface) and >10² enhancement throughout the majority of the nanowire core (FIG. 24). Note that the actual emission rate is also related to the frequency matching between the cavity resonance frequency and the homogeneously broadened emitter frequency¹⁹⁻²¹. Ω-shaped plasmonic cavities showed the quality factor of ˜30, corresponding to a spectral broadening (FWHM) of ˜84 meV for the cavity mode at 2.505 eV (peak A in FIG. 18a). In contrast, the homogeneous broadening for single (high-density) phonon-assisted hot luminescence channel is typically quite small (˜15 meV) (e.g., peak 2 in FIG. 19a), so that the frequency matching would be likely to be near unity under resonant condition, which means that the emission rate enhancement is very close to the calculated Purcell factor. Therefore, such large field enhancement enables hot-carrier recombination before their thermalization (FIG. 17a), which would otherwise lead to poor radiative quantum yields (<10⁻⁴). Internal quantum efficiency for hot luminescence in plasmonic silicon was estimated to be 1.4% (see Methods), with an enhancement of >10³ in comparison to bulk silicon, which can be further improved by optimizing the plasmonic cavity structure.

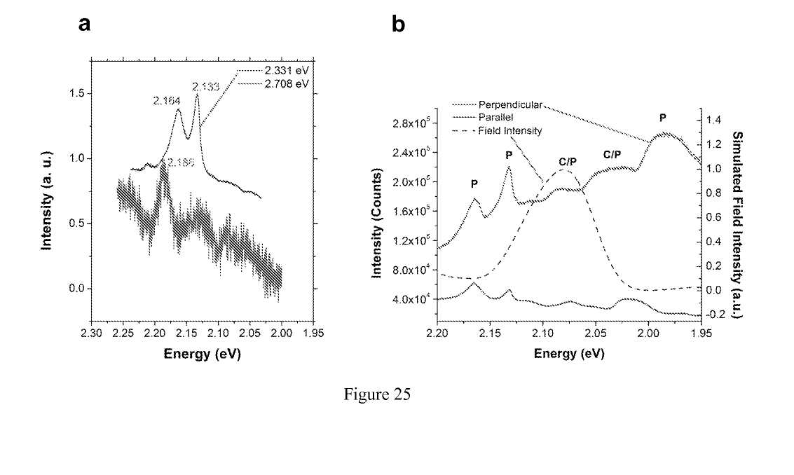

Polarization-dependent photoluminescence measurements were made. Because surface plasmon polaritons are transverse-magnetic waves at the metal-dielectric interface²², the electric-field of plasmon cavity modes should be polarized perpendicular to the nanowire long axis. Indeed, the resonant-sized plasmon cavity (d=70 nm) showed perpendicularly-polarized hot luminescence bands with the emission polarization ratio, ρ, of 0.56 where ρ=(I_{⊥}−I_{//})/(I_{⊥}+I_{//}) (FIG. 19a). The polarized emission bands are exactly overlapped with the calculated field intensity inside the cavity (FIG. 19a); however, the finer peak structures observed within the cavity resonances are more pronounced for the perpendicularly-polarized emission and cannot be simulated by the field calculations. On the other hand, for the non-resonant case (at diameters showing very low photon counts), distinct bands attributed to cavity plasmons and phonon-assisted hot-carrier emission were observed. Perpendicularly-polarized hot luminescence spectra (FIG. 19b) along with the calculated cavity field intensity for a nonresonant plasmonic nanowire (d=50 nm) reveals both the cavity modes and the phonon-assisted luminescence bands, while the parallel polarization shows very little counts. The simulated cavity field intensity as a function of energy fits reasonably well with the observed modes; interestingly, the sharp peaks assigned to phonon-assisted hot luminescence bands (“P”) occur at almost the same energies as resonant-sized cavities, but their mismatch with the cavity plasmon bands (“C”) makes the emission process less likely. Even though the plasmon cavity modes (“C”) are off resonance from the highly emissive hot-carrier states (“P”) in the nonresonant case, the cavity modes can interact with hot-carrier states with lower density of states and emit, albeit with low counts. To ensure that the sharp peaks originate from the phonon-assisted hot luminescence bands, spectra were measured at different laser excitation energy (2.331 eV), confirming that the shift of peak (“P”) position and the interplay between the “P” and “C” peaks (FIG. 25).

Phonon-assisted hot luminescence is enhanced when the hot-carriers assisted by phonons with the highest density of states are resonantly coupled with the cavity plasmons. The simulated size dependence of plasmon cavity modes (FIG. 19c) shows that the exact resonance between the three strong hot luminescence bands observed at 2.51, 2.34, and 2.18 eV and the plasmon cavity modes occurs at the Si nanowire size of ˜70 nm. This simulated prediction is further verified in the size-dependent photoluminescence spectra of nanowires with diameters ranging from 40 to 80 nm (FIG. 19d). As the diameter approaches the resonant size of ˜70 nm, the hot luminescence intensity is drastically increased, reflecting a perfect resonance between the hot-carriers assisted by high-density of states phonons and the cavity plasmons.

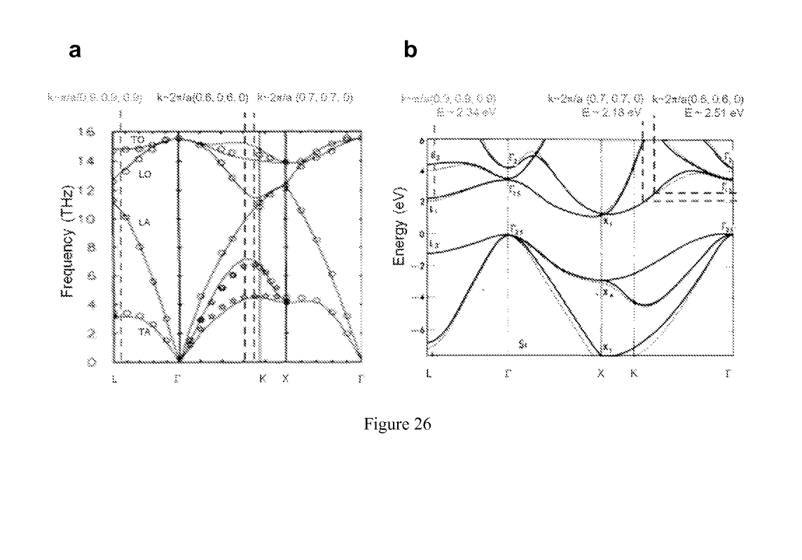

Light emission is possible when phonons scatter the hot-carriers to the almost vertical light-line (k˜0). This phonon assisted scattering process should satisfy momentum conservation, k′=kₑ±q≈0, where k′ and kₑ are the momentum values of hot-carriers at the light line and at the initial electronic state respectively, and q is the phonon momentum. Thus, the hot-carrier population would depend on the modes with the highest phonon density of states where phonon dispersion has almost zero slope²³, and those specific phonons can scatter the hot-carrier efficiently to the light line. The phonon dispersion of silicon along the <110> direction shows that the density of states is relatively high for momentum values of ˜2π/a(0.6, 0.6, 0) for transverse optical (TO) and transverse acoustic (TA) and ˜2π/a(0.7, 0.7, 0) for longitudinal optical (LO) and TA phonons, situated between Γ and K points²⁴ (FIG. 26a). Taking into account the electronic dispersion of silicon²⁵ (FIG. 26b), the same momentum values of ˜2π/a(0.6, 0.6, 0) and ˜2π/a(0.7, 0.7, 0) correspond to the strong hot luminescence bands at 2.51 and 2.18 eV respectively. Furthermore, the hot luminescence band at 2.34 eV corresponds to the zone edge phonon at k˜π/a(0.9, 0.9, 0.9) with high density of states near the L-point along <111> direction.

The absorption process upon laser excitation involves interaction with a phonon, followed by intra-band relaxation of hot-carriers by phonon emission (lower k values); this can occur by either a 1-phonon process involving an optical phonon near the Brillouin zone center (Γ-point) with low k values, or a 2-phonon (acoustic) process with k values with opposite signs near the Brillouin zone boundaries²⁶. Because the density of states of transverse acoustic (TA) phonons near the zone boundary is much higher than that of longitudinal acoustic (LA) phonons in crystalline silicon as seen in their dispersion²⁴, intra-band relaxation process would be dominated by 2-TA phonons. Based on the known phonon dispersion in silicon²⁷, the phonon-assisted hot luminescence processes has been explained elsewhere herein. The broadening of the peaks with increasing energy separation from the laser excitation suggests that many other phonon relaxation pathways also start to contribute.

This work demonstrates the unique interplay of three (quasi) particle systems; carriers, phonons and cavity plasmons, which provide an interesting test bed to study such complex processes that can also lead to new properties in engineered materials not found otherwise. The ability to obtain visible light emission from silicon devices which are compatible with lengthscales in current electronics (>20 nm) opens up new ways to integrate active Si-based photonics with other conventional functionalities. This method obtains light emission from any indirect bandgap semiconductor and is useful for the fabrication of monolithic devices utilizing optics for ultrafast data processing.

Thus, in one embodiment the present disclosure provides plasmonic nanowire devices. These devices suitably include a core that comprises a direct bandgap material; an interlayer that at least partially surmounts the core; and a shell that at least partially surmounts the interlayer.

In some embodiments, a plasmonic nanocavity is defined by the nanowire. and a diameter of the core corresponds to a plasmonic resonant cavity mode. A plasmonic cavity may be formed by the nanowire and a thickness of the interlayer corresponds to a plasmonic resonant cavity mode.

A cross-sectional dimension (e.g, diameter, radius, and the like) of the core may be in the range of from about 10 nm to about 1 micrometer, or from about 100 nm to about 500 nm. As explained elsewhere herein, it should be understood that the core may be circular in cross-section, but may also be triangular, hexagonal, or otherwise polygonal or even irreglular or non-symmetric in cross-section. A core may include CdS, CdSe, CdTe, ZnO, ZnS, ZnSe, GaN, GaAs, InP, InAs, InN, CuO, PbS, PbSe, PbTe, and the like and combinations thereof. An interlayer may include, e.g., SiO₂, Si₃N₄, MaF₂, TiO₂, Al₂O₃, HfO₂, MgO, and the like or any combination thereof. A shell may include a metal, e.g., Au, Al, Pt, Cu, Pd, graphene, and the like or any combination thereof. Ag is considered an especially suitable shell material.

Also disclosed are plasmonic nanowire devices, the devices including a core having a diameter and comprising a bandgap material; an interlayer having a thickness and at least partially surmounting the core; and a shell at least partially surmounting the interlayer, wherein a plasmonic nanocavity is formed and a diameter of the core or a thickness of the interlayer corresponds to a plasmonic resonant cavity mode.

The bandgap material may be an indirect bandgap material or a direct bandgap material, depending on the user's needs. The core may have a cross-sectional dimension in the range of from about 10 nm to about 1 micrometer, or even from about 100 nm to about 500 nm. The core may include, e.g., CdS, CdSe, CdTe, ZnO, ZnS, ZnSe, GaN, GaAs, InP, InAs, InN, CuO, PbS, PbSe, PbTe, and the like or any combination thereof. Alternatively, the core may include Si, Ge, Si—Ge, SiC, GaP, and the like or any combination thereof.

An interlayer of the disclosed devices may include SiO₂, Si₃N₄, MaF₂, TiO₂, Al₂O₃, HfO₂, MgO, and the like or any combination thereof. Suitable shell materials are described elsewhere herein, and may include Ag, Au, Al, Pt, Cu, Pd, graphene and the like or any combination thereof.

Further provided are plasmonic nanowire devices comprising a core having a cross-sectional dimension and comprising an indirect bandgap material; an interlayer having a thickness and at least partially surmounting the core; and a shell that at least partially surmounts the interlayer.

A cross-sectional dimension of the core or a thickness of the interlayer may corresponds to a plasmonic resonant cavity mode. Suitable core materials are described elsewhere herein, as are suitable interlayer and shell materials.

The present disclosure also provides emitters. An emitter may include a excitation source; suitable excitation sources may be either optical (such as a laser, or white-light source) or electrical.

The emitter also suitably includes a plasmonic nanowire device. Such a device suitably includes a core having a cross-sectional dimension and comprising a bandgap material; an interlayer having a thickness and at least partially surmounting the core; a metallic shell that at least partially surmounts the interlayer, wherein a diameter of the core or a thickness of the interlayer corresponds to the plasmonic resonant cavity mode of the plasmonic nanowire; and a detector capable of detecting an emission from the plasmonic nanowire. A detector that can count photons (exiting the nanowire) is considered especially suitable.

The disclosed devices may be applied in a number of fields, e.g., silicon photonic-circuit components, silicon-based light emitting diodes (LEDs), ultrasensitive biodetectors. deep sub-wavelength optoelectronic devices, which may be modulated at very high frequencies due to the very short excited state lifetime.

Methods

Device Fabrication

Single-crystalline undoped silicon nanowires (Sigma-Aldrich) were dispersed in ethanol and transferred onto a 150 μm-thick glass substrate. A 5 nm SiO₂ interlayer was deposited by atomic layer deposition (ALD) (Cambridge Nanotech) by alternating O₃, 3-Aminopropyltriethoxysilane (APTES), and H₂O pulses at a temperature of 150° C. A 100 nm Ag thin film was coated to form an Ω-shaped plasmonic cavity by using an e-beam evaporator at a low deposition rate of 0.2 Å/s for the first 50 nm and 0.5 Å/s for the remaining film. Ag bowtie structures were fabricated on Si substrates after etching the native oxide. Silicon substrate was covered with 5 nm SiO₂ layer grown via ALD. After the ALD process, bowties were patterned by electron-beam lithography followed by the deposition of 30 nm-thick Ag by electron-beam evaporation.

Optical Measurements at Room Temperature

Silicon nanowires coupled with Ω-shaped plasmonic nanocavities were optically excited through the 150 μm-thick glass substrate using a home-built microscope equipped with a 60×, 0.7 NA objective (Nikon), having a spatial detection resolution of 500 nm. Planar Si with the bowtie structures was excited from the top side. A continuous wave argon-ion laser (Coherent) tuned at a wavelength of 457.9 nm was focused to pump the individual nanowires with the beam spot size of 2 μm on the sample with an excitation power of ˜250 kW/cm². For UV excitation, a frequency doubled femtosecond pulsed Ti:Sapphire laser (Chameleon) was tuned at a central wavelength of 355.7 nm. Photoluminescence spectra were collected using a spectrometer (Acton-SP 500i) and a cooled charge coupled device (CCD) (Pixis 2K, Princeton Instruments) with a spectral resolution of 0.5 nm.

Numerical Calculation

Simulations were performed for the silicon nanowire coupled with the Ω-shaped plasmonic nanocavity structures with a pulsed point dipole source inside the cavity using a commercial finite-difference-time-domain (FDTD) software package (Lumerical). The eigenmodes, quality factors (Q), and field intensity profiles were analyzed by Fourier transforming the calculated time-domain data to the frequency-domain. By performing three-dimensional FDTD simulations, the Purcell factor, Γ/Γ₀=3Q(λ/2n)³/2πV_{eff}, was obtained by calculating the effective mode volume (V_{eff}) where λ and n is the free space wavelength and refractive index respectively¹⁸. The effective mode volume of the plasmonic cavity modes can be expressed by²⁸

$${V}_{eff} = \frac{\int ɛ ( r ) {E}^{2} ( r ) {d}^{3} r}{{( ɛ ( r ) {E}^{2} ( r ) )}_{dip}}$$

where ∈(r) is the material dielectric constant. E_{dip} was taken in the silicon medium at the position where a dipole emitter would experience the calculated Purcell factor and the electric field intensity is integrated over the entire mode structure. The frequency-dependent real and imaginary parts of the dielectric function of Ag were obtained via an analytical fit to experimental data²⁹ and the real and imaginary parts of refractive indices of Si and SiO₂ were taken from Palik, Handbook of Optical Constants of Solids (1998).

Quantum Efficiency Estimation

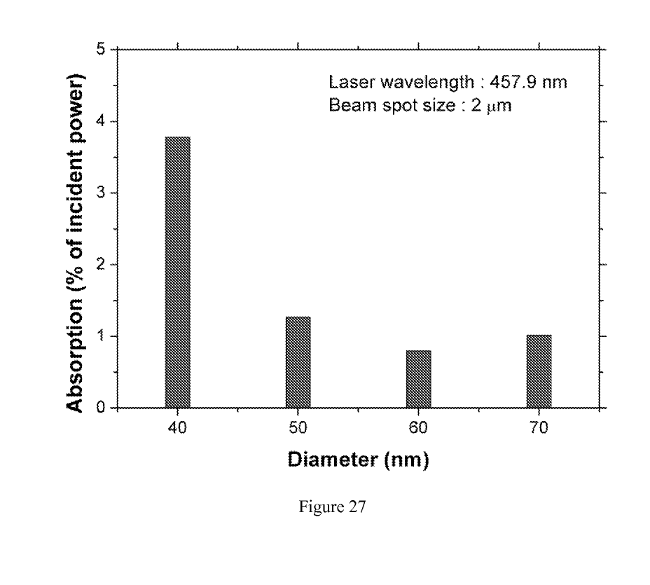

Optical power collection efficiency was estimated in the optical fiber coupled spectrometer with CCD, which was used for the photoluminescence measurements. By measuring a known laser power from the integrated counts with taking into account the quantum yield and the sensitivity of the CCD, the collection efficiency was estimated to be 1%. From the integrated photon counts of the photoluminescence spectrum from the sample, the photoluminescence power through the objective was measured to be 0.8 nW. Three-dimensional FDTD calculations were carried out for Si nanowire coupled with Ω-shaped cavity (d=70 nm, l=8 μm) to obtain an overall far-field out-coupling efficiency of 0.059% through the entire emission spectral range after considering the numerical aperture of objective, resulting in the actual power of 1.4 μW emitted from Si. In addition, the absorption efficiency of 1% for the same plasmonic silicon with Ω-shaped cavity was calculated at the laser wavelength of 457.9 nm with a 2 μm beam size (FWHM) using the FDTD technique to fully take into account possible absorption enhancement due to the antenna effect (FIG. 27), giving rise to the absorbed power in Si of 100 μW at the incident laser power of 10 mW. Therefore, the quantum efficiency of 1.4% was estimated by taking the ratio of the emission power from Si (1.4 μW) to the absorbed power in Si (100 μW).

Discussion of Phonon-assisted Hot Luminescence Process (FIGS. 19 and 26)

The broad spectrum of hot luminescence originates from a large number of discrete phonon assisted events with many pathways interacting with various types of phonons on each crystallographic direction of the electronic dispersion of silicon. However, the existence of specific phonon modes with high density of states (zero slopes in dispersion) provides highly emissive pathways for the phonon assisted hot luminescence process, which due to the energy and momentum conservation, results in the observed three strong emission bands and additional fine peak structure.

These data, which compare resonant (˜70 nm Si diameter; FIG. 18a) and non-resonant cavities (FIG. 19), clearly indicates that the quantum yield of hot luminescence process is maximized when emissive hot carriers assisted by phonon modes with high density of states interact resonantly with plasmon cavity modes (see size-dependent data and calculations in FIG. 19). The three strong hot luminescence bands observed at 2.51, 2.34, and 2.18 eV for the resonant plasmonic silicon (FIG. 18a), can be explained by resonant enhancement by the plasmonic cavity modes, while the sharp peaks on top of these bands can be further explained by efficient emission channels due to specific phonons having very high density of states involved in the hot luminescence process.

It should be noted that light emission is only possible when a phonon scatters the hot carriers to the almost vertical light line (k˜0). This phonon assisted scattering process should follow energy and momentum conservation, k′=kₑ±q≈0, where k′ and kₑ are the momentum values of hot carriers at the light line and at the initial electronic state respectively, and q is the phonon momentum. Thus, the emissive hot carrier population would depend on the modes with the highest phonon density of states where phonon dispersion has almost zero slope²³, and those specific phonons can scatter the hot carrier efficiently to the light line. The phonon dispersion of silicon along the <110> direction shows that the density of states is relatively high for momentum values of ˜2π/a(0.6, 0.6, 0) for transverse optical (TO) and transverse acoustic (TA) and ˜2π/a(0.7, 0.7, 0) for longitudinal optical (LO) and TA phonons, situated between Γ and K points (FIG. 26a). Taking into account the electronic dispersion of silicon (FIG. 26b), at the same momentum values of ˜2π/a(0.6, 0.6, 0) and ˜2π/a(0.7, 0.7, 0) correspond to the strong hot luminescence bands at 2.51 and 2.18 eV where the phonons with the momentum values satisfy the momentum conservation for the hot luminescence processes. Furthermore, the hot luminescence band at 2.34 eV corresponds to the zone edge phonon at k˜π/a(0.9, 0.9, 0.9) with high density of states near the L-point along <111> direction.

As revealed in the polarization-dependent measurements along with the simulations, the hot luminescence can be strongly enhanced when the specific emission channels with high density of states are resonant with the cavity plasmons. It is reasonable to believe that the sharp peaks originate from phonons with the highest density of states. From these spectral peak positions (labeled 1-5), the relaxation and emission processes involving carrier-phonon interactions can be inferred. The absorption process upon laser excitation involves interaction with a phonon, followed by the intra-band relaxation of hot carriers by emitting phonons. The intra-band energy relaxation process involves carrier scattering with phonons with small k; this can occur by either a 1-phonon process involving an optical phonon near the Brillouin zone center (Γ-point) with small k values, or a 2-phonon (acoustic) process with k values with opposite signs near the Brillouin zone boundaries. Because the density of states of transverse acoustic (TA) phonons near the zone boundary is much higher than that of longitudinal acoustic (LA) phonons in crystalline silicon as seen in their dispersion, intra-band relaxation process is expected to be dominated by 2-TA phonons.

In the first strong emission band (at ˜2.51 eV), only the two peaks (peaks 1 and 2) are predominant and no further strong peak at ˜32 meV lower than peak 2 is observed in the measurements. This can be explained by taking into account the narrow energy window for the phonon modes with the highest density of states, which correspond to the first strong emission band (FIG. 26). The first “P” peak in FIG. 19b appears at 2.476 eV, which is 31.3 meV lower than the peak “2” (2.509 eV) in FIG. 19a, and the first “P” peak is the next phonon assisted event (with additional 2TA relaxation) to the peak “2” process. As discussed above, in principle, the hot luminescence consists of various emission pathways with extremely low quantum yields, which can be distributed in a broad energy range below the laser excitation. Even though the plasmon cavity modes for the off-resonance case do not overlap exactly with the phonons with the highest density of states, the cavity modes can still interact with hot carrier states coupled with low density phonon modes, which would feed the cavity modes but leading to low emission counts (the peak “C” in FIG. 19b). The first peak for the parallel polarization is positioned at the free spectral range of the calculated field intensity (at ˜2.55 eV), and the first peak for the perpendicular polarization coincides with the cavity field intensity peaked at ˜2.63 eV with a sharp cutoff above 2.58 eV due to a dichroic mirror in the measurement setup, as discussed in the manuscript.

Although numerous characteristics and advantages of the present invention have been set forth in the foregoing description, together with details of the structure and function of the invention, the disclosure is illustrative only, and changes may be made in details within the principles of the invention to the full extent indicated by the broad general meaning of the terms in which the appended claims are expressed.

What is claimed:

1. A plasmonic nanowire, comprising:
a core that comprises a direct bandgap material;
an interlayer that at least partially surmounts the core; and
a shell that at least partially surmounts the interlayer.

2. The plasmonic nanowire of claim 1, wherein a plasmonic nanocavity is defined by the nanowire. and a diameter of the core corresponds to a plasmonic resonant cavity mode.

3. The plasmonic nanowire of claim 1, wherein a plasmonic cavity is formed by the nanowire and a thickness of the interlayer corresponds to a plasmonic resonant cavity mode.

4. The plasmonic nanowire of claim 2, wherein the diameter of the core is in the range of from about 10 nm to about 1 micrometer.

5. The plasmonic nanowire of claim 1, wherein the core comprises CdS, CdSe, CdTe, ZnO, ZnS, ZnSe, GaN, GaAs, InP, InAs, InN, CuO, PbS, PbSe, PbTe, or any combination thereof.

6. The plasmonic nanowire of claim 5, wherein the interlayer comprises SiO₂, Si₃N₄, MaF₂, TiO₂, Al₂O₃, HfO₂, MgO, or any combination thereof.

7. The plasmonic nanowire of claim 6, wherein the shell comprises Ag, Au, Al, Pt, Cu, Pd, graphene, or any combination thereof.

8. A plasmonic nanowire comprising:
a core having a diameter and comprising a bandgap material;
an interlayer having a thickness and at least partially surmounting the core; and
a shell at least partially surmounting the interlayer, wherein a plasmonic nanocavity is formed and a diameter of the core or a thickness of the interlayer corresponds to a plasmonic resonant cavity mode.

9. The plasmonic nanowire of claim 8, wherein the bandgap material comprises an indirect bandgap material.

10. The plasmonic nanowire of claim 8, whether the bandgap material comprises a direct bandgap material.

11. The plasmonic nanowire of claim 8, wherein the diameter of the core is in the range of from about 10 nm to about 1 micrometer.

12. The plasmonic nanowire of claim 10, wherein the core comprises CdS, CdSe, CdTe, ZnO, ZnS, ZnSe, GaN, GaAs, InP, InAs, InN, CuO, PbS, PbSe, PbTe, or any combination thereof.

13. The plasmonic nanowire of claim 8, wherein the interlayer comprises SiO₂, Si₃N₄, MaF₂, TiO₂, Al₂O₃, HfO₂, MgO, or any combination thereof.

14. The plasmonic nanowire of claim 8, wherein the shell comprises Ag, Au, Al, Pt, Cu, Pd, graphene, or any combination thereof.

15. The plasmonic nanowire of claim 9, wherein the core comprises Si, Ge, Si—Ge, SiC, GaP, or any combination thereof.

16. A plasmonic nanowire comprising:
a core having a diameter and comprising an indirect bandgap material;
an interlayer having a thickness and at least partially surmounting the core; and
a shell that at least partially surmounts the interlayer.

17. The plasmonic nanowire of claim 16, wherein a diameter of the core or thickness of the interlayer corresponds to a plasmonic resonant cavity mode.

18. The plasmonic nanowire of claim 16, wherein the core comprises Si, Ge, Si—Ge, SiC, GaP, or any combination thereof.

19. The plasmonic nanowire of claim 16, wherein the interlayer comprises SiO₂, Si₃N₄, MaF₂, TiO₂, Al₂O₃, HfO₂, MgO, or any combination thereof.

20. The plasmonic nanowire of claim 16, wherein the shell comprises Ag, Au, Al, Pt, Cu, Pd, graphene, or any combination thereof.

21. An emitter, comprising:
a excitation source;
a plasmonic nanowire comprising:
a core having a diameter and comprising a bandgap material;
an interlayer having a thickness and at least partially surmounting the core;
a metallic shell that at least partially surmounts the interlayer,
wherein a diameter of the core or a thickness of the interlayer corresponds to the plasmonic resonant cavity mode of the plasmonic nanowire;
and
a detector capable of detecting an emission from the plasmonic nanowire.
